(19) United States
(12) Patent Application Publication
(10) Pub. No.: US 2025/0133898 A1
(43) Pub. Date: Apr. 24, 2025

(54) LIGHT-EMITTING DEVICE, DISPLAY PANEL AND DISPLAY APPARATUS

(71) Applicant: BOE TECHNOLOGY GROUP CO., LTD., Beijing (CN)

(72) Inventors: Haiyan SUN, Beijing (CN); Xiaojin ZHANG, Beijing (CN); Dan WANG, Beijing (CN)

(73) Assignee: BOE TECHNOLOGY GROUP CO., LTD., Beijing (CN)

(21) Appl. No.: 18/705,592

(22) PCT Filed: May 17, 2023
(86) PCT No.: PCT/CN2023/094806

§ 371 Date: Apr. 29, 2024

(51) Int. Cl. H10K 50/12; H10K 85/30; H10K 85/40; H10K 85/60; H10K 101/00; H10K 101/10; H10K 101/40

(52) U.S. Cl. CPC H10K 50/12; H10K 85/346; H10K 85/40; H10K 85/615; H10K 85/654; H10K 85/6572; H10K 85/6574; H10K 85/6576; H10K 85/658; H10K 2101/10; H10K 2101/40; H10K 2101/90

(57) ABSTRACT

A light-emitting device includes at least one light-emitting unit. A light-emitting layer of the at least one light-emitting unit includes a first host material, a second host material, and a first light-emitting material. Photons emitted by the first light-emitting material include photons emitted due to energy obtained by fluorescence resonance energy transfer of the first and/or second host material and photons emitted due to excitons formed by recombination of electrons and holes. A ratio of a number of the photons emitted by the first light-emitting material to a number of photons emitted by the light-emitting layer is greater than 80%; a ratio of a number of the photons emitted by the first light-emitting material due to the energy obtained by fluorescence resonance energy transfer of the first and/or second host material to the number of the photons emitted by the first light-emitting material is greater than 60%.

### CROSS-REFERENCE TO RELATED APPLICATION

The present application is a national phase entry under 35 USC 371 of International Patent Application No. PCT/CN2023/094806, filed on May 17, 2023, which is incorporated herein by reference in its entirety.

### TECHNICAL FIELD

The present disclosure relates to the field of display technologies, and in particular, to a light-emitting device, a display panel and a display apparatus.

### BACKGROUND

Organic light-emitting diode (OLED) display panels have the advantages of self-illumination, high color gamut, high saturation, high response speed and the like, and are widely used in display screens such as mobile phones, tablets, and car displays.

### SUMMARY

In an aspect, a light-emitting device is provided. The light-emitting device includes a first electrode and a second electrode that are arranged in sequence, and at least one light-emitting unit disposed between the first electrode and the second electrode. The at least one light-emitting unit includes a light-emitting layer, and the light-emitting layer includes: a first host material, a second host material, and a first light-emitting material. Photons emitted by the first light-emitting material include: photons emitted due to energy obtained by fluorescence resonance energy transfer of the first host material and/or the second host material, and photons emitted due to excitons formed by recombination of electrons and holes. A ratio of a number of the photons emitted by the first light-emitting material to a number of photons emitted by the light-emitting layer is greater than 80%; a ratio of a number of the photons emitted by the first light-emitting material due to the energy obtained by fluorescence resonance energy transfer of the first host material and/or the second host material to the number of the photons emitted by the first light-emitting material is greater than 60%.

In some embodiments, a mass proportion of the first light-emitting material in the light-emitting layer is less than or equal to 5% and greater than or equal to 0.5%.

In some embodiments, an absolute value of a difference between a highest occupied molecular orbital level of the first light-emitting material and greater one of a highest occupied molecular orbital level of the first host material and a highest occupied molecular orbital level of the second host material is less than or equal to 0.25 eV.

In some embodiments, a singlet energy level of the first host material is greater than a singlet energy level of the first light-emitting material; a singlet energy level of the second host material is greater than the singlet energy level of the first light-emitting material; a triplet energy level of the first host material is greater than a triplet energy level of the first light-emitting material; and a triplet energy level of the second host material is greater than the triplet energy level of the first light-emitting material.

In some embodiments, a lowest unoccupied molecular orbital level of the first light-emitting material is greater than smaller one of a lowest unoccupied molecular orbital level of the first host material and a lowest unoccupied molecular orbital level of the second host material.

In some embodiments, a hole mobility of the first host material is greater than an electron mobility of the first host material; an electron mobility of the second host material is greater than a hole mobility of the second host material; a ratio of the hole mobility of the first host material to the electron mobility of the second host material is greater than or equal to 0.1.

In some embodiments, an electron mobility of the first host material is greater than a hole mobility of the first host material; a hole mobility of the second host material is greater than an electron mobility of the second host material; a ratio of the hole mobility of the second host material to the electron mobility of the first host material is greater than or equal to 0.1.

In some embodiments, at least one of an internal quantum efficiency of the first host material and an internal quantum efficiency of the second host material is greater than or equal to 30%.

In some embodiments, a ratio of a mass proportion of the first host material in the light-emitting layer to a mass proportion of the second host material in the light-emitting layer is greater than or equal to 0.25 and less than or equal to 4.

In some embodiments, an absolute value of a difference between a highest occupied molecular orbital level of the first host material and a highest occupied molecular orbital level of the second host material is less than or equal to 0.25 eV.

In some embodiments, the first light-emitting material is selected from any of structures represented by the following general formula I.

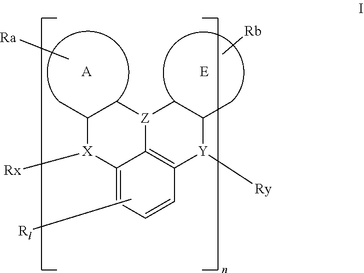

X, Y and Z are the same or different, and are independently selected from any of C(Re), N, B, P, P═O, Si(Re), S and a single bond; a value of n is selected from any of 1, 2, 3 and 4; A and E are the same or different, and are independently selected from any of five-membered or six-membered carbocycles, five-membered or six-membered carboheterocycles, and fused rings; and Ra, Rb, Rx, Ry, R₁ and Re are the same or different, and are independently selected from any of hydrogen, deuterium, cyano, substituted or unsubstituted C5-C50 aryl, and substituted or unsubstituted C1-C50 alkyl.

In some embodiments, the first light-emitting material is selected from any of structures represented by the following general formula II.

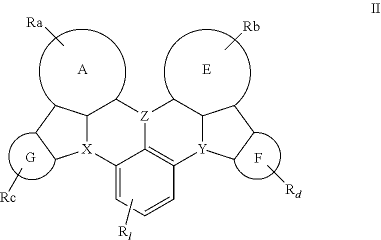

X, Y and Z are independently selected from any of C(Re), N, B, P, P═O, Si(Re), S and a single bond; and Z is different from X and Y; A, E, F and G are the same or different, and are independently selected from any of five-membered or six-membered carbocycles, five-membered or six-membered carboheterocycles and fused rings, and A, E, F and G are not all six-membered carbocycles; in a case where G is a six-membered carbocycle, F is not a six-membered carbocycle or does not exist; Ra, Rb, Rc, Rd, R₁ and Re are the same or different, and are independently selected from any of hydrogen, deuterium, cyano, substituted or unsubstituted C5-C50 aryl, and substituted or unsubstituted C1-C50 alkyl.

In some embodiments, the first light-emitting material is selected from any of structures represented by the following general formula III.

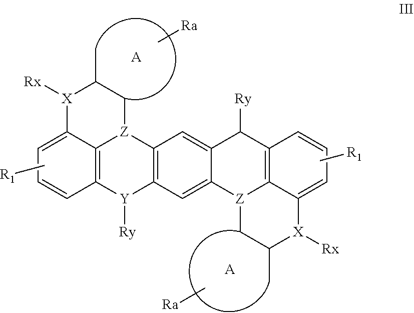

X, Y and Z are independently selected from any of C(Re), N, B, P, P═O, Si(Re), S and a single bond; X and Y are the same or different, and Z is different from X and Y; A is selected from five-membered or six-membered carbocycle, or five-membered or six-membered carboheterocycle; Ra, Rx, Ry, R₁ and Re are the same or different, and are independently selected from any of hydrogen, deuterium, cyano, substituted or unsubstituted C5-C50 aryl, and substituted or unsubstituted C1-C50 alkyl.

In some embodiments, the first light-emitting material is selected from any of structures represented by the following general formula IV.

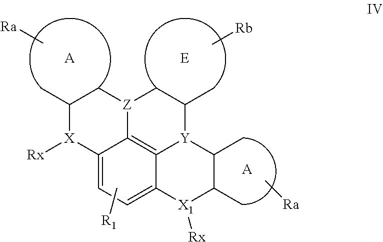

X, Y, Z and X₁ are independently selected from any of C(Re), N, B, P, P═O, Si(Re), S and a single bond, and in a case where Z and Y are the same, X and X₁ are the same; in a case where Z and Y are different, X and X₁ are different; A and E are the same or different, and are independently selected from five-membered or six-membered carbocycles or carboheterocycles; A and E are not all six-membered carbocycles; Ra, Rb, Rx, R₁ and Re are the same or different, and are independently selected from any of hydrogen, deuterium, cyano, substituted or unsubstituted C5-C50 aryl, and substituted or unsubstituted C1-C50 alkyl.

In some embodiments, the first light-emitting material is selected from any of structures represented by the following general formula V.

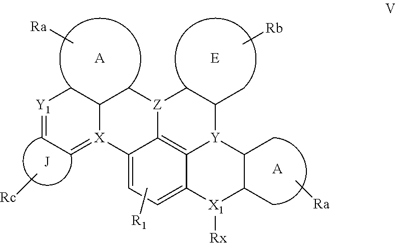

X, Y, Z, X₁ and Y₁ are independently selected from any of C(Re), N, B, P, P═O, Si(Re), S and a single bond; in a case where Z is the same as Y, X is the same as X₁; in a case where Z is different from Y, X is different from X₁, and Y₁ is different from X; A, E, and J are the same or different, and are independently selected from five-membered or six-membered carbocycles or carboheterocycles, and A, E, and J are not all six-membered carbocycles; Ra, Rb, Rc, Rx, R₁ and Re are the same or different, and are independently selected from any of hydrogen, deuterium, cyano, substituted or unsubstituted C5-C50 aryl, and substituted or unsubstituted C1-C50 alkyl.

In some embodiments, a molecular weight of the first light-emitting material is less than or equal to 1250.

In some embodiments, the light-emitting layer further includes a second light-emitting material; a singlet energy level of the second light-emitting material is less than a singlet energy level of the first light-emitting material; and a triplet energy level of the second light-emitting material is greater than a triplet energy level of the first light-emitting material.

In some embodiments, a mass proportion of the second light-emitting material in the light-emitting layer is less than or equal to 5% and greater than or equal to 0.1%.

In another aspect, a display panel is provided. The display panel includes the light-emitting device as described in any of the above embodiments and a driving circuit. The driving circuit is used to drive the light-emitting device to emit light.

In yet another aspect, a display apparatus is provided. The display apparatus includes the display panel as described in any of the above embodiments and a driver chip. The driver chip is used to drive the display panel to perform display.

### BRIEF DESCRIPTION OF THE DRAWINGS

In order to describe technical solutions in the present disclosure more clearly, the accompanying drawings to be used in some embodiments of the present disclosure will be introduced briefly. Obviously, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display apparatus, in accordance with some embodiments of the present disclosure;

FIG. 2 is a structural diagram of a display panel, in accordance with some embodiments of the present disclosure;

FIG. 3 is a structural diagram of a light-emitting device, in accordance with some embodiments of the present disclosure;

FIG. 4 is a structural diagram of another light-emitting device, in accordance with some embodiments of the present disclosure;

FIG. 5 is an emission spectrum diagram of a light-emitting device, in accordance with some embodiments of the present disclosure; and

FIG. 6 is an emission spectrum diagram of another light-emitting device, in accordance with some embodiments of the present disclosure.

### DETAILED DESCRIPTION

The technical solutions in some embodiments of the present disclosure will be described clearly and completely with reference to the accompanying drawings; obviously, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to”. In the description of the specification, the terms such as “one embodiment”, “some embodiments”, “exemplary embodiments”, “example”, “specific example”, or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics may be included in any one or more embodiments or examples in any suitable manner.

The terms “first” and “second” are used for descriptive purposes only, and are not to be construed as indicating or implying a relative importance or implicitly indicating a number of indicated technical features. Thus, a feature defined with “first” or “second” may explicitly or implicitly include one or more of the features. In the description of the embodiments of the present disclosure, the term “a plurality of” or “the plurality of” means two or more unless otherwise specified.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

The term such as “about”, “substantially”, and “approximately” as used herein includes a stated value and an average value within an acceptable range of deviation of a particular value. The acceptable range of deviation is determined by a person of ordinary skill in the art, considering measurement in question and errors associated with measurement of a particular quantity (i.e., limitations of a measurement system).

The term such as “parallel,” “perpendicular,” or “equal” as used herein includes a stated condition and a condition similar to the stated condition. A range of the similar condition is within an acceptable deviation range, and the acceptable deviation range is determined by a person of ordinary skill in the art, considering measurement in question and errors associated with measurement of a particular quantity (i.e., the limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be, for example, that a difference between two equals is less than or equal to 5% of either of the two equals.

It will be understood that, when a layer or element is referred to as being on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views that are schematic illustrations of idealized embodiments. In the accompanying drawings, thicknesses of layers and areas of regions are enlarged for clarity. Thus, variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a curved feature. Therefore, the regions shown in the accompanying drawings are schematic in nature, and their shapes are not intended to show actual shapes of the regions in a device, and are not intended to limit the scope of the exemplary embodiments.

It will be noted that, for example, “11˜1” shown in the accompanying drawings of the present disclosure indicates that Component 11 belongs to Component 1; for example, “130B˜130” indicates that the blue light-emitting unit 130B belongs to the light-emitting unit 130. Other similar signs shown in the accompanying drawings also follow the above description.

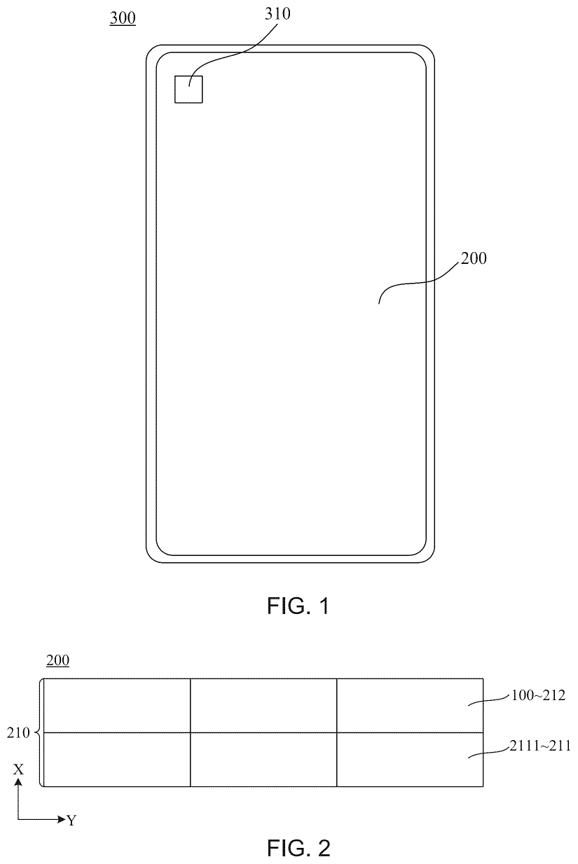

Referring to FIG. 1, some embodiments of the present disclosure provide a display apparatus 300, and the display apparatus 300 includes a display panel 200.

In some examples, the display apparatus 300 may be, for example, an organic light-emitting diode (OLED) display panel.

For example, referring to FIG. 1, the display apparatus 300 further includes a driver chip 310. The driver chip 310 is configured to drive the display panel 200 to perform display.

In addition, the display apparatus 300 may further include an under-screen camera and an under-screen fingerprint recognition sensor, so that the display apparatus 300 is capable of implementing various functions such as taking pictures, video recording, fingerprint recognition, or face recognition.

The display apparatus 300 may be any display apparatus that displays an image whether in motion (e.g., a video) or stationary (e.g., a still image), and whether literal or graphical. More specifically, it is expected that the embodiments may be implemented in or associated with various electronic devices. The various electronic devices may include (but is not limit to), for example, mobile telephones, wireless devices, personal data assistants (PDAs), hand-held or portable computers, GPS receivers/navigators, cameras, MP4 video players, video cameras, game consoles, watches, clocks, calculators, TV monitors, flat panel displays, computer monitors, car displays (e.g., odometer displays), navigators, cockpit controllers and/or displays, camera view displays (e.g., rear view camera displays in vehicles), electronic photos, electronic billboards or indicators, projectors, building structures, packagings and aesthetic structures (e.g., a display for an image of a piece of jewelry).

In some embodiments, referring to FIG. 2, the display panel 200 includes a display substrate 210. The display substrate 210 includes an array layer 211 and a light-emitting functional layer 212. The light-emitting functional layer 212 is located on a side of the array layer 211. The array layer 211 includes a plurality of driving circuits 2111. The light-emitting functional layer 212 includes a plurality of light-emitting devices 100. In some examples, the plurality of driving circuits 2111 may be coupled to the plurality of light-emitting devices 100 in a one-to-one correspondence. In some other examples, a driving circuit 2111 may be coupled to multiple light-emitting devices 100, or multiple driving circuits 2111 may be coupled to a light-emitting device 100.

For example, in the display panel 200, the driving circuit 2111 may generate a driving current. Each light-emitting device 100 may emit light due to the driving action of the driving current generated by the respective driving circuit 2111. The light emitted by the plurality of light-emitting devices 100 cooperates with each other, so that the display panel 200 realizes the display function.

In some implementations, when the OLED display device is in use, there will be a problem of greenish and reddish at a low gray scale. The display images of the OLED display apparatus is formed by a mixture of three colors of red (R), green (G) and blue (B), but the current efficiency decay in different tendencies of the three colors of red (R), green (G) and blue (B) at different gray scales, resulting in the problem of greenish and reddish at a low gray scale.

In some other implementations, when the OLED display device is in use, there will be a problem of color cast at different gray scales. The efficiency difference between low gray scale and high gray scale is too large, resulting in the display difference at different gray scales.

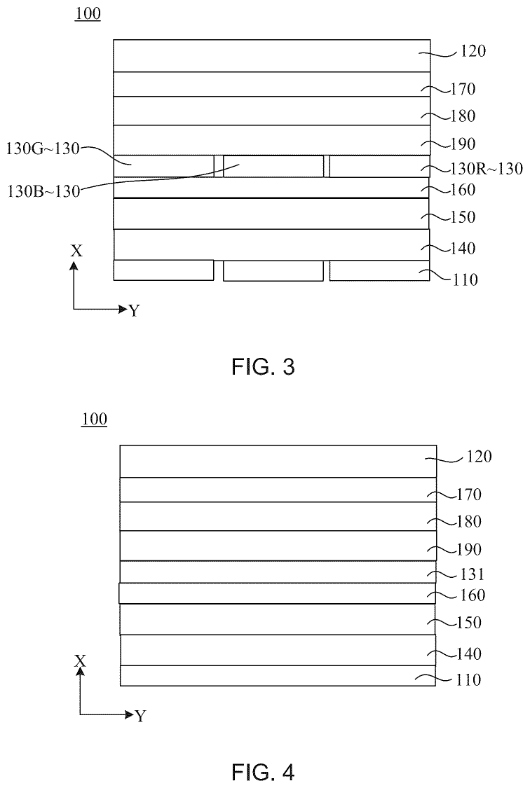

Based on this, referring to FIG. 3, some embodiments of the present disclosure provide a light-emitting device 100. The light-emitting device 100 includes: a first electrode 110 and a second electrode 120 that are arranged in sequence, and at least one light-emitting unit 130 arranged between the first electrode 110 and the second electrode 120. The at least one light-emitting unit 130 includes a light-emitting layer 131, and the light-emitting layer 131 includes: a first host material H1, a second host material H2, and a first light-emitting material D1. Photons emitted by the first light-emitting material D1 include: photons emitted due to energy obtained by fluorescence resonance energy transfer of the first host material H1 and/or the second host material H2, and photons emitted due to excitons formed by recombination of electrons and holes. A ratio of the number of photons emitted by the first light-emitting material D1 to the number of photons emitted by the light-emitting layer 131 is greater than 80%; a ratio of the number of photons emitted by the first light-emitting material D1 due to energy obtained by fluorescence resonance energy transfer of the first host material H1 and/or the second host material H2 to the number of the photons emitted by the first light-emitting material D1 is greater than 60%.

In some examples, referring to FIG. 3, a second direction Y is perpendicular to a first direction X. The first electrode 110 may be an anode, and the second electrode 120 may be a cathode. During operation, voltages are respectively applied to the first electrode 110 and the second electrode 120 to generate an electric field between them, which may drive the holes in the anode and the electrons in the cathode to recombine in the light-emitting unit 130, thereby emitting light. The emitted light includes light emitted by the photons emitted by the first light-emitting material D1; the photons emitted by the first light-emitting material D1 include photons emitted due to energy obtained by fluorescence resonance energy transfer of the first host material H1 and/or the second host material H2 and photons emitted due to excitons formed by recombination of electrons and holes.

For example, in order to ensure that the light-emitting device 100 is able to effectively emit light, the first electrode 110 (anode) is made of a material with a high work function, such as a material with a work function greater than 6 eV; the second electrode 120 (cathode) is made of a material with a low work function, such as a material whose work function is less than a set value, and the set value may be in a range of 2.0 eV to 3.0 eV, inclusive. Thus, the holes in the anode and the electrons in the cathode may effectively migrate to the light-emitting unit 130 under the driving of the electric field to combine to emit light.

In some examples, the light-emitting device 100 is a bottom-emission light-emitting device, and the material of the first electrode 110 may be a transparent conductive metal oxide material to prevent the first electrode 110 from blocking light. For example, the material of the first electrode 110 may be indium tin oxide (ITO) or indium zinc oxide (IZO); a thickness of the first electrode 110 may be in a range of 80 nm to 200 nm, inclusive. The average reflectivity of the material of the first electrode 110 in the visible light range may be in a range of 85% to 95%, inclusive. The material of the second electrode 120 may be a metal material. For example, the material of the second electrode 120 may be magnesium, silver, aluminum, or magnesium-silver alloy. In a case where the material of the second electrode 120 is magnesium-silver alloy, the mass ratio of magnesium to silver is in a range of 3:7 to 1:9, inclusive; the second electrode 120 is formed by, for example, evaporation. A thickness of the second electrode 120 may be greater than or equal to 80 nm to ensure good reflectivity.

In some other examples, the light-emitting device 100 is a top-emission light-emitting device, and the material of the first electrode 110 may be of a composite layer structure composed of metal/conductive metal oxide. For example, the material of the first electrode 110 may be of a composite layer structure of silver/indium tin oxide or a composite layer structure of silver/indium zinc oxide; a thickness of the metal layer may be in a range of 80 nm to 100 nm, inclusive; and a thickness of the conductive metal oxide may be in a range of 5 nm to 10 nm, inclusive. The average reflectivity of the material of the first electrode 110 in the visible light range may be in a range of 85% to 95%, inclusive. The material of the second electrode 120 may be a metal material. For example, the material of the second electrode 120 may be magnesium, silver, aluminum, or magnesium-silver alloy. In a case where the material of the second electrode 120 is magnesium-silver alloy, the mass ratio of magnesium to silver is in a range of 3:7 to 1:9, inclusive; the second electrode 120 is formed by, for example, evaporation. A thickness of the second electrode 120 may be in a range of 10 nm to 20 nm, inclusive. A transmittance, at 530 nm, of the material of the second electrode 120 is in a range of 50% to 60%, inclusive.

In some embodiments, referring to FIG. 3, in order to improve the luminous efficiency of the light-emitting device 100, at least one of a hole injection layer (HIL) 140, a hole transport layer (HTL) 150, and an electron blocking layer (EBL) 160 is provided between the first electrode 110 and the light-emitting unit 130, and at least one of an electron injection layer (EIL) 170, an electron transport layer (ETL) 180, and a hole blocking layer (HBL) 190 is provided between the second electrode 120 and the light-emitting unit 130. By providing the film layers of the hole injection layer 140, the hole transport layer 150, the electron blocking layer 160, the electron injection layer 170, the electron transport layer 180, and the hole blocking layer 190, which is equivalent to provide a transition step between the anode and the light-emitting unit 130 and to provide a transition step between the cathode and the light-emitting unit 130, it is possible to reduce the height of the potential barrier that needs to be overcome for carrier transitions, thereby improving the luminous efficiency.

For example, the hole injection layer 140 is configured to reduce the potential barrier of the holes to improve the hole injection efficiency. The hole injection layer 140 may be a single layer film formed of a single material, and the material of the hole injection layer 140 is, for example, 11-hexacarbonitrile (HAT-CN) or copper phthalocyanine (CuPc). Alternatively, the hole injection layer 140 may be formed by performing P-type dopping on the hole transport material; for example, N,N′-Bis-(1-naphthalenyl)-N, N′-bis-phenyl-(1,1′-biphenyl)-4,4′-diamine (NPB) is doped with 2,3,5,6-Tetrafluoro-7,7,8,8-tetracyanoquinodimethane (F4TCNQ), or 4,4′-Cyclohexylidenebis[N, N-bis(4-methylphenyl) aniline] (TAPC) is doped with manganese trioxide (MnO3); the doping concentration may be in a range of 0.5% to 10%, inclusive. A thickness of the hole injection layer 140 may be in a range of 5 nm to 20 nm, inclusive.

For example, the hole transport layer 150 is configured to transport holes, and the material of the hole transport layer 150 may be a material with a high hole mobility, such as carbazole materials. The hole transport layer 150 may be formed by evaporation. The highest occupied molecular orbital (HOMO) level of the hole transport layer 150 may be in a range of 5.2 eV to 5.6 eV, inclusive. A thickness of the hole injection layer 150 may be in a range of 100 nm to 140 nm, inclusive.

For example, the electron blocking layer 160 is configured to block electrons and excitons generated in the light-emitting unit 130; a thickness of the electron blocking layer 160 may be in a range of 1 nm to 10 nm, inclusive.

For example, a thickness of the electron injection layer 170 may be in a range of 0.5 nm to 2 nm, inclusive.

For example, a thickness of the electron transport layer 180 may be in a range of 20 nm to 70 nm, inclusive.

For example, the hole blocking layer 190 is configured to block holes and excitons generated in the electron transport layer 180; a thickness of the hole blocking layer 190 may be in a range of 2 nm to 10 nm, inclusive.

For example, a thickness of the light-emitting unit 130 is in a range of 10 nm to 30 nm, inclusive; the light-emitting layer 131 of the light-emitting unit 130 includes the first host material H1, the second host material H2, and the first light-emitting material D1; the doping proportion of the first host material H1 is greater than or equal to 50%; the doping proportion of the second host material H2 is greater than or equal to 5% and less than or equal to 50%; the doping proportion of the first light-emitting material D1 is greater than or equal to 0.5% and less than or equal to 5%. The second host material H2 has delayed fluorescence characteristics. The singlet energy level (S1(H2)) of the second host material H2 and the triplet energy level (T1(H2)) of the second host material H2 satisfy: S1(H2)−T1(H2)≤0.2 eV; a ratio of the luminous efficiency of the second host material H2 to the total luminous efficiency of the light-emitting unit 130 is less than 10%.

In some embodiments, referring to FIG. 3, there are at least two light-emitting units 130, and the second electrodes 120, each arranged with the respective light-emitting unit 130 in sequence, are connected to be a whole-layer structure. That is, the second electrode 120 may be a common electrode shared by the light-emitting units 130. The hole injection layers 140, each arranged with the respective light-emitting unit 130, may also be connected to be a whole-layer structure. That is, the hole injection layer 140 may be a common film layer shared by the light-emitting units 130. Also, the hole transport layer 150, the electron blocking layer 160, the hole blocking layer 190, the electron injection layer 170, and the electron transport layer 180 may each be a common film layer shared by the light-emitting units 130.

In some embodiments, referring to FIGS. 2 and 3, the at least one light-emitting unit 130 includes three light-emitting units 130; for example, the three light-emitting units 130 are respectively a red light-emitting unit 130R, a green light-emitting unit 130G, and a blue light-emitting unit 130B; the red light-emitting unit 130R emits red light, the green light-emitting unit 130G emits green light, and the blue light-emitting unit 130B emits blue light. The three light-emitting units 130 are arranged in the second direction Y, and the second direction Y is perpendicular to the first direction X. Due to the arrangement of the three light-emitting units 130, the luminance (gray scale) of the light-emitting units 130 of different colors may be adjusted respectively, and various colors may be displayed through color combination and superposition, thereby achieving full-color display of the display panel 200.

In some other embodiments, at least two light-emitting units 130 include M light-emitting units 130, where M is a positive integer greater than three; the M light-emitting units 130 are arranged in the second direction Y, and the second direction Y is perpendicular to the first direction X. For example, the number of red light-emitting units 130R is at least two, and/or the number of green light-emitting units 130G is at least two, and/or the number of blue light-emitting units 130B is at least two.

The at least one light-emitting unit 130 includes a light-emitting layer 131, and the light-emitting layer 131 includes a first host material H1, a second host material H2, and a first light-emitting material D1. For example, the first host material H1 and the second host material H2 are configured to transfer fluorescence resonance energy to the first light-emitting material D1, and the first light-emitting material D1 is configured to emit photons to achieve the purpose of emitting light. Moreover, the first light-emitting material D1 may also reduce the quenching of excitons at the triplet energy level of the first host material H1 and/or the second host material H2, which may reduce the difference in the number of excitons at different gray scales to a certain extent, thereby reducing the efficiency attenuation ΔΕ.

The photons emitted by the first light-emitting material D1 include: photons emitted due to energy obtained by fluorescence resonance energy transfer of the first host material H1 and/or the second host material H2, and photons emitted due to excitons formed by recombination of electrons and holes. The energy that the first light-emitting material D1 emits photons may be any one of the following four energies.

First energy: energy of fluorescence resonance energy transfer of the first host material H1 and the second host material H2, i.e., energy transferred between the first host material H1, the second host material H2 and the first light-emitting material D1. For example, an order in which the first energy is transferred may be the first host material H1, the second host material H2, and the first light-emitting material D1; or the order in which the first energy is transferred may be the second host material H2, the first host material H1, the first light-emitting material D1, which are not limited here.

Second energy: energy of fluorescence resonance energy transfer of the first host material H1, i.e., fluorescence resonance energy transferred from the first host material H1 to the first light-emitting material D1.

Third energy: energy of fluorescence resonance energy transfer of the second host material H2, i.e., fluorescence resonance energy transferred from the second host material H2 to the first light-emitting material D1.

Fourth energy: energy of the excitons formed by recombination of electrons and holes in the first light-emitting material D1, i.e., energy of the excitons formed by recombination of electrons and holes in the first light-emitting material D1 itself.

It will be noted that in the following description in the embodiments in the present disclosure, the photons emitted due to the energy obtained by fluorescence resonance energy transfer of the first host material H1 and/or the second host material H2 are photons emitted due to the first energy, the second energy and the third energy, which referred to as photons emitted through a first channel; the photons emitted due to excitons formed by recombination of electrons and holes are photons emitted due to the fourth energy, which referred to as photons emitted through a second channel.

In some embodiments, the first host material H1 and the second host material H2 in the light-emitting layer 131 will undergo radiative transition and emit photons. Therefore, the photons emitted by the light-emitting layer 131 include at least: photons emitted by the first host material H1, photons emitted by the second host material H2, and the photons emitted by the first light-emitting material D1.

The ratio of the number of the photons emitted by the first light-emitting material D1 to the number of the photons emitted by the light-emitting layer 131 is greater than 80%, that is, a ratio of the number of photons emitted by other materials in the light-emitting layer 131 except for the first light-emitting material D1 to the number of the photons emitted by the light-emitting layer 131 is less than 20%. It will be noted that the photons emitted by the first light-emitting material D1 include at least photons emitted through the first channel and photons emitted through the second channel. The other materials except for the first light-emitting material D1 may be the second host material H2, or may be the first host material H1 or other materials, which is not limited here.

It will be understood that, the wavelength of light emitted by the second host material H2, the first host material H1 and other materials is inconsistent with the wavelength of the target light emitted by the light-emitting device 100, which cannot meet the light-emitting requirements of the light-emitting device 100. Furthermore, the light emitted by the materials such as the second host material H2 and the first host material H1 includes both the light emitted at the singlet energy level and the light emitted at the triplet energy level. The light emitting process at the triplet energy level is relatively slow and easy to occur quenching, which may affect the overall luminous efficiency of the light-emitting device 100; in addition, the relatively slow light emitting process at the triplet energy level will also lead to a great difference in the number of excitons under different current conditions, which is manifested as a great efficiency attenuation ΔE, resulting in display difference at the different gray scales. In the embodiments of the present disclosure, the ratio of the number of the photons emitted by the first light-emitting material D1 to the number of the photons emitted by the light-emitting layer 131 is greater than 80%, so that the number of the photons emitted by the first light-emitting material D1 is relatively great, and the number of the photons emitted by the materials such as the second host material H2 and the first host material H1 is relatively small, which may accelerate the overall light emitting process of the light-emitting layer 131, and reduce the efficiency attenuation ΔE; moreover, it is possible to enable the wavelength of the emitted light to meet the light-emitting requirements of the light-emitting device 100, so that the overall luminous efficiency of the light-emitting device 100 is improved.

With the above settings, in some embodiments, the efficiency attenuation ΔE may be less than 6%; in some other embodiments, the efficiency attenuation ΔE may be less than 5%.

It will be noted that the efficiency attenuation ΔE of the light-emitting unit 130 refers to a ratio of the absolute value of the difference between the current efficiency E1 at low current density and the current efficiency E2 at high current density to the maximum current efficiency

$$Max ( E 1 , E 2 ) , i . e . , Δ E = \frac{\vert E 1 - E 2 \vert}{Max ( E 1 , E 2 )} \times 100 \% .$$

The maximum current efficiency Max(E1, E2) refers to the greater one of the two of the current efficiency E1 at low current density and the current efficiency E2 at high current density.

The efficiency attenuation ΔER of the red light-emitting unit 130R, the efficiency attenuation ΔEG of the green light-emitting unit 130G, and the efficiency attenuation ΔEB of the blue light-emitting unit 130B are respectively:

$$Δ ER = \frac{\vert ER 1 - ER 2 \vert}{Max ( ER 1 , ER 2 )} \times 100 \% \\ Δ EG = \frac{\vert EG 1 - EG 2 \vert}{Max ( EG 1 , EG 2 )} \times 100 \% \\ Δ EB = \frac{\vert EB 1 - EB 2 \vert}{Max ( EB 1 , EB 2 )} \times 100 \%$$

ER1, EG1, and EB1 are respectively the current efficiencies of the red light-emitting unit 130R, the green light-emitting unit 130G, and the blue light-emitting unit 130B at low current density; ER2, EG2, and EB2 are respectively the current efficiencies of the red light-emitting unit 130R, the green light-emitting unit 130G, and the blue light-emitting unit 130B at high current density; Max(ER1,ER2) refers to the greater one of the two of the current efficiency ER1 of the red light-emitting unit 130R at low current density and the current efficiency ER2 of the red light-emitting unit 130R at high current density; Max(EG1,EG2) refers to the greater one of the two of the current efficiency EG1 of the green light-emitting unit 130G at low current density and the current efficiency EG2 of the green light-emitting unit 130G at high current density; Max(EB1,EB2) refers to the greater one of the two of the current efficiency EB1 of the blue light-emitting unit 130B at low current density and the current efficiency EB2 of the blue light-emitting unit 130B at high current density.

For example, the low current density refers to a current density of 1 mA/cm²; the high current density refers to a current density of 15 mA/cm².

The ratio of the number of the photons emitted by the first light-emitting material D1 due to the energy obtained by fluorescence resonance energy transfer of the first host material H1 and/or the second host material H2 to the number of the photons emitted by the first light-emitting material D1 is greater than 60%. That is, a ratio of the number of the photons emitted through the first channel to the number of the photons emitted by the first light-emitting material D1 is greater than 60%, and a ratio of the number of the photons emitted through the second channel to the number of the photons emitted by the first light-emitting material D1 is less than 40%. It will be understood that in a case where the first light-emitting material D1 emits photons through the first channel, the energy is transferred through the first host material H1 and/or the second host material H2, and more excitons are generated. The ratio of the number of the photons emitted through the first channel to the number of the photons emitted by the first light-emitting material D1 is greater than 60%, so that relatively more photons are emitted through the first channel and relatively few photons are emitted through the second channel. Thus, it is possible to improve the energy utilization rate of the light-emitting unit 130, thereby improving the luminous efficiency of the light-emitting device 100.

For example, the number of photons emitted through the first channel, the number of photons emitted through the second channel, and the number of photons emitted by the first light-emitting material D1 may be obtained by fitting the transient attenuation curve. The transient attenuation curve may be measured using a transient spectrometer. During measurement, a square wave signal not lower than the driving voltage is input to the light-emitting device 100. The transient spectrometer is, for example, a transient fluorescence spectrometer of model FLS1000; the voltage value of the driving voltage is, for example, 3 V.

For example, the first host material H1 and the second host material H2 are two materials with a high doping proportion in the light-emitting layer 131, and the electron and hole transport properties of the first host material H1 and the second host material H2 are different from each other. That is, among the first host material H1 and the second host material H2, one is a high-holes material, and the other is a high-electrons material.

In some embodiments, the mass proportion of the first light-emitting material D1 in the light-emitting layer 131 is less than or equal to 5% and greater than or equal to 0.5%. For example, the mass proportion of the first light-emitting material D1 in the light-emitting layer 131 is 0.5%, 1.0%, 1.5%, 2.0%, 3.0%, 4.0%, 5.0%, or the like, which is not limited here.

In a case where the mass proportion of the first light-emitting material D1 in the light-emitting layer 131 is less than 0.5%, in the fluorescence resonance energy transfer process of the first host material H1 and/or the second host material H2, i.e., in the process of emitting photons through the first channel, there is too little first light-emitting material D1 that capable of receiving energy, which limits the luminous efficiency of the first light-emitting material D1 and may not meet the requirement that the ratio of the number of photons emitted by the first light-emitting material D1 to the number of photons emitted by the light-emitting layer 131 is greater than 80%; moreover, it is possible to increase the number of photons emitted by the first host material H1 and/or the second host material H2, while the photons emitted by the first host material H1 and/or the second host material H2 are prone to quenching, resulting in a decrease in the overall luminous efficiency of the light-emitting device 100. In a case where the mass proportion of the first light-emitting material D1 in the light-emitting layer 131 is greater than 5%, the number of photons emitted through the second channel is increased; during the process of emitting photons through the second channel, excitons are prone to quenching, resulting in the loss of excitons, which leads to a reduction in luminous efficiency.

In some embodiments, an absolute value of a difference between the highest occupied molecular orbital level HOMO(D1) of the first light-emitting material D1 and greater one Max(HOMO(H1),HOMO(H2)) of the highest occupied molecular orbital level HOMO(H1) of the first host material H1 and the highest occupied molecular orbital level HOMO(H2) of the second host material H2 is less than or equal to 0.25 eV; that is, |HOMO(D1)−Max(HOMO(H1),HOMO(H2))|≤0.25 eV.

In a case where |HOMO(D1)−Max(HOMO(H1),HOMO(H2))| is great, for example, greater than 0.25 eV, the loss of excitons will occur during the fluorescence resonance energy transfer process of the first host material H1 and/or the second host material H2, resulting in the reduction in the luminous efficiency of the light-emitting unit 130. By setting |HOMO(D1)−Max(HOMO(H1),HOMO(H2))| to be less than or equal to 0.25 eV, the luminous efficiency of the light-emitting unit 130 may be improved.

In some embodiments, the singlet energy level S1(H1) of the first host material H1 is greater than the singlet energy level S1(D1) of the first light-emitting material D1; the singlet energy level S1(H2) of the second host material H2 is greater than the singlet energy level S1(D1) of the first light-emitting material D1; the triplet energy level T1(H1) of the first host material H1 is greater than the triplet energy level T1(D1) of the first light-emitting material D1; the triplet energy level T1(H2) of the second host material H2 is greater than the triplet energy level T1(D1) of the first light-emitting material D1; that is, S1(H1)>S1(D1);S1(H2)>S1(D1);T1(H1)>T1(D1);T1(H2)>T1(D1).

It will be understood that, in a case of S1(H1)>S1(D1), and S1(H2)>S1(D1), at the singlet energy level, the first host material H1 may transmit energy to the first light-emitting material D1, and the second host material H2 may transmit energy to the first light-emitting material D1, thereby achieving the effective energy transmission from the first host material H1 and/or the second host material H2 to the first light-emitting material D1 at the singlet energy level. In a case of T1(H1)>T1(D1), and T1(H2)>T1(D1), at the triplet energy level, the first host material H1 may transmit energy to the first light-emitting material D1, and the second host material H2 may transmit energy to the first light-emitting material D1, thereby achieving the effective energy transmission from the first host material H1 and/or the second host material H2 to the first light-emitting material D1 at the triplet energy level.

For example, the singlet energy level S1(H1) of the first host material H1 is greater than the singlet energy level S1(H2) of the second host material H2; the singlet energy level S1(H2) of the second host material H2 is greater than the singlet energy level S1(D1) of the first light-emitting material D1; the triplet energy level T1(H1) of the first host material H1 is greater than the triplet energy level T1(H2) of the second host material H2; the triplet energy level T1(H2) of the second host material H2 is greater than the triplet energy level T1(D1) of the first light-emitting material D1; that is, S1(H1)>S1(H2)>S1(D1), T1(H1)>T1(H2)>T1(D1). In this way, at the singlet energy level, the order of the energy transmission is the first host material H1, the second host material H2, and the first light-emitting material D1; at the triplet energy level, the order of the energy transmission is the first host material H1, the second host material H2 and the first light-emitting material D1; and thus, the energy transmission efficiency is improved, and the luminous efficiency of the light-emitting unit 130 is improved.

In some embodiments, the lowest unoccupied molecular orbital level LOMO (D1) of the first light-emitting material D1 is greater than smaller one Min(LOMO(H1),LOMO(H2)) of lowest unoccupied molecular orbital level LOMO(H1) of the first host material H1 and lowest unoccupied molecular orbital level LOMO(H2) of the second host material H2; that is, LOMO (D1)>Min(LOMO(H1),LOMO(H2)).

It will be understood that in a case where the lowest unoccupied molecular orbital level LOMO (D1) of the first light-emitting material D1 is greater than the smaller one Min(LOMO(H1),LOMO(H2)) of the lowest unoccupied molecular orbital level LOMO(H1) of the first host material H1 and the lowest unoccupied molecular orbital level LOMO(H2) of the second host material H2, it is possible to reduce the capture of electrons by the first light-emitting material D1, thereby avoiding the destruction of the balance between electrons and holes caused by the capture of electrons by the first light-emitting material D1.

In some embodiments, a hole mobility of the first host material H1 is greater than an electron mobility of the first host material H1; an electron mobility of the second host material H2 is greater than a hole mobility of the second host material H2; a ratio of the hole mobility of the first host material H1 to the electron mobility of the second host material H2 is greater than or equal to 0.1.

It will be understood that in a case where the hole mobility of the first host material H1 is greater than the electron mobility of the first host material H1, the first host material H1 is a high-holes material; in a case where the electron mobility of the second host material H2 is greater than the hole mobility of the second host material H2, the second host material H2 is a high-electrons material; by setting the ratio of the hole mobility of the first host material H1 to the electron mobility of the second host material H2 is greater than or equal to 0.1, the number of electrons and the number of holes are balanced, and a ratio of the number of electrons to the number of holes is close to 1:1, which is conducive to the recombination in the second host material H2 to form excitons. For example, the ratio of the hole mobility of the first host material H1 to the electron mobility of the second host material H2 may be 0.1, 0.2, 0.5, 1, 2, 3, 5, or the like, which is not limited here.

It will be noted that the ratio of the hole mobility of the first host material H1 to the electron mobility of the second host material H2 is greater than or equal to 0.1, which includes the following two cases.

First case: the hole mobility of the first host material H1 is greater than or equal to the electron mobility of the second host material H2; that is, a ratio of the hole mobility of the first host material H1 to the electron mobility of the second host material H2 is greater than or equal to 1.

Second case: the hole mobility of the first host material H1 is less than the electron mobility of the second host material H2; and the ratio of the hole mobility of the first host material H1 to the electron mobility of the second host material H2 is greater than or equal to 0.1 and less than 1.

In some other embodiments, the electron mobility of the first host material H1 is greater than the hole mobility of the first host material H1; the hole mobility of the second host material H2 is greater than the electron mobility of the second host material H2; the ratio of the hole mobility of the second host material H2 to the electron mobility of the first host material H1 is greater than or equal to 0.1.

It will be understood that in a case where the electron mobility of the first host material H1 is greater than the hole mobility of the first host material H1, the first host material H1 is a high-electrons material; in a case where the hole mobility of the second host material H2 is greater than the electron mobility of the second host material H2, the second host material H2 is a high-holes material; by setting the ratio of the hole mobility of the second host material H2 to the electron mobility of the first host material H1 is greater than or equal to 0.1, the number of electrons and the number of holes are balanced, and a ratio of the number of electrons to the number of holes is close to 1:1, which is conducive to the recombination in the second host material H2 to form excitons. For example, the ratio of the hole mobility of the second host material H2 to the electron mobility of the first host material H1 may be 0.1, 0.3, 0.5, 1, 2, 3, 6, or the like, which is not limited here.

It will be noted that the ratio of the hole mobility of the second host material H2 to the electron mobility of the first host material H1 is greater than or equal to 0.1, which includes the following two cases.

First case: the hole mobility of the second host material H2 is greater than or equal to the electron mobility of the first host material H1; that is, a ratio of the hole mobility of the second host material H2 to the electron mobility of the first host material H1 is greater than or equal to 1.

Second case: the hole mobility of the second host material H2 is less than the electron mobility of the first host material H1; a ratio of the hole mobility of the second host material H2 to the electron mobility of the first host material H1 is greater than or equal to 0.1 and less than 1.

In some embodiments, at least one of the internal quantum efficiency of the first host material H1 and the internal quantum efficiency of the second host material H2 is greater than or equal to 30%.

In related arts, the internal quantum efficiency (IQE) is a conventional indicator that reflects the luminous performance of materials, specifically referring to the percentage of the number of photons radiated by excitons recombination inside the device to the number of carriers injected into the device. The higher the internal quantum efficiency of a material, the greater the number of excitons it produces. In a case where the internal quantum efficiency of a certain material is greater than or equal to 30%, the material may be a delayed fluorescent material or a phosphorescent material, but may not be a fluorescent material.

Since at least one of the internal quantum efficiency of the first host material H1 and the internal quantum efficiency of the second host material H2 is greater than or equal to 30%, at least one of the first host material H1 and the second host material H2 is a delayed fluorescent material or a phosphorescent material; that is, at least one of the first host material H1 and the second host material H2 has a high exciton yield and may utilize the energies of singlet excitons and triplet excitons to emit light, so that the luminous efficiency of the light-emitting unit 130 is improved.

In some embodiments, a ratio of the mass proportion of the first host material H1 in the light-emitting layer 131 to the mass proportion of the second host material H2 in the light-emitting layer 131 is greater than or equal to 0.25 and less than or equal to 4.

It will be understood that, among the first host material H1 and the second host material H2, one is a high-holes material, and the other is a high-electrons material. The ratio of the mass proportion of the first host material H1 in the light-emitting layer 131 to the mass proportion of the second host material H2 in the light-emitting layer 131 is greater than or equal to 0.25 and less than or equal to 4, so that the number of electrons and the number of holes are balanced, which is conducive to the recombination in the high-electrons material to form excitons.

For example, the ratio of the mass proportion of the first host material H1 in the light-emitting layer 131 to the mass proportion of the second host material H2 in the light-emitting layer 131 may be 0.25, 0.5, 0.8, 1, 1.5, 2, 3, 4, or the like, which is not limited here.

In some embodiments, an absolute value of a difference between the highest occupied molecular orbital level HOMO(H1) of the first host material H1 and the highest occupied molecular orbital level HOMO(H2) of the second host material H2 is less than or equal to 0.25 eV; that is, |HOMO(H1)−HOMO(H2)|≤0.25 eV.

In a case where the absolute value of the difference between the highest occupied molecular orbital level HOMO(H1) of the first host material H1 and the highest occupied molecular orbital level HOMO(H2) of the second host material H2 is great, a complex is easily to be formed between the first host material H1 and the second host material H2, and the complex will generate new singlet energy levels and new triplet energy levels, resulting in that the energy transmission direction during the light-emitting process of the light-emitting unit 130 is inconsistent with the set energy transmission direction, which affects the luminous efficiency of the light-emitting unit 130. In the embodiments of the present disclosure, the absolute value of the difference between the highest occupied molecular orbital level HOMO(H1) of the first host material H1 and the highest occupied molecular orbital level HOMO(H2) of the second host material H2 is less than or equal to 0.25 eV, so that the energy may be transmitted in the set direction during the light emitting process of the light-emitting unit 130.

In some embodiments, the structural formula of the first host material H1 may be any one of H1-1 to H1-30 as shown below.

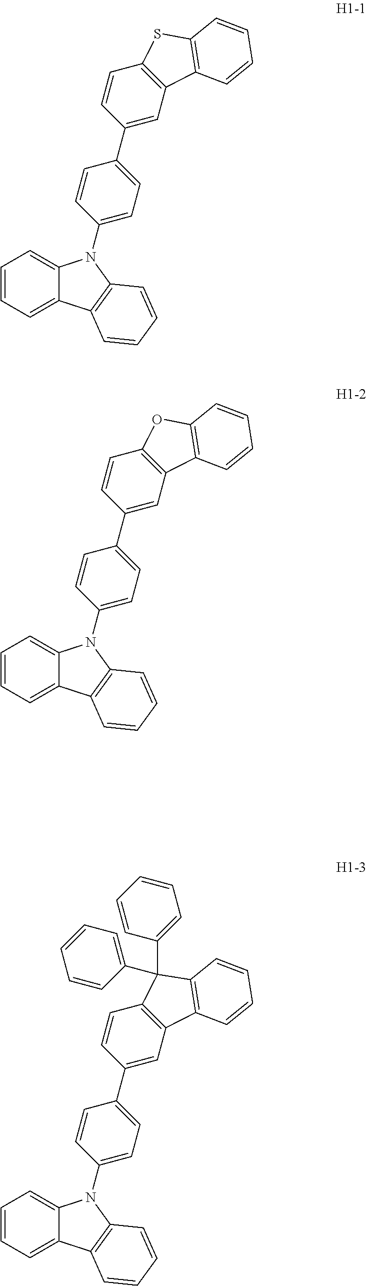 [SMILES: c1ccc2c(c1)sc1ccc(-c3ccc(-n4c5ccccc5c5ccccc54)cc3)cc12 ; c1ccc2c(c1)oc1ccc(-c3ccc(-n4c5ccccc5c5ccccc54)cc3)cc12 ; c1ccc(C2(c3ccccc3)c3ccccc3-c3cc(-c4ccc(-n5c6ccccc6c6ccccc65)cc4)ccc32)cc1]

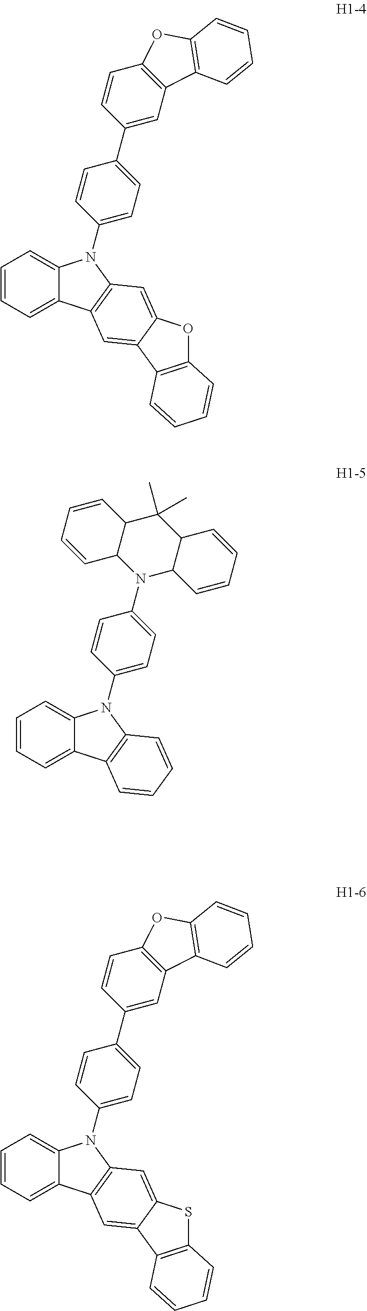 [SMILES: c1ccc2c(c1)oc1ccc(-c3ccc(-n4c5ccccc5c5cc6c(cc54)oc4ccccc46)cc3)cc12 ; CC1(C)C2C=CC=CC2N(c2ccc(-n3c4ccccc4c4ccccc43)cc2)C2C=CC=CC21 ; c1ccc2c(c1)oc1ccc(-c3ccc(-n4c5ccccc5c5cc6c(cc54)sc4ccccc46)cc3)cc12]

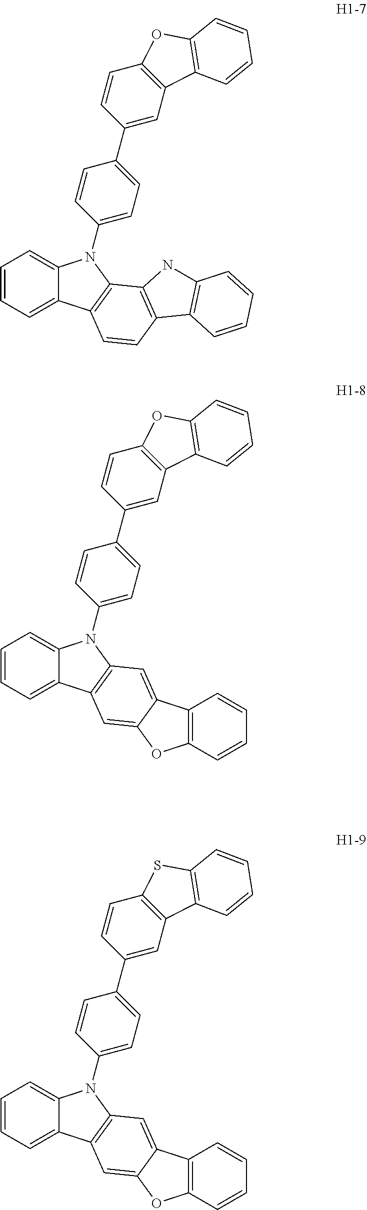 [SMILES: c1ccc2c(c1)[nH]c1c2ccc2c3ccccc3n(-c3ccc(-c4ccc5oc6ccccc6c5c4)cc3)c21 ; c1ccc2c(c1)oc1ccc(-c3ccc(-n4c5ccccc5c5cc6oc7ccccc7c6cc54)cc3)cc12 ; c1ccc2c(c1)oc1cc3c4ccccc4n(-c4ccc(-c5ccc6sc7ccccc7c6c5)cc4)c3cc12]

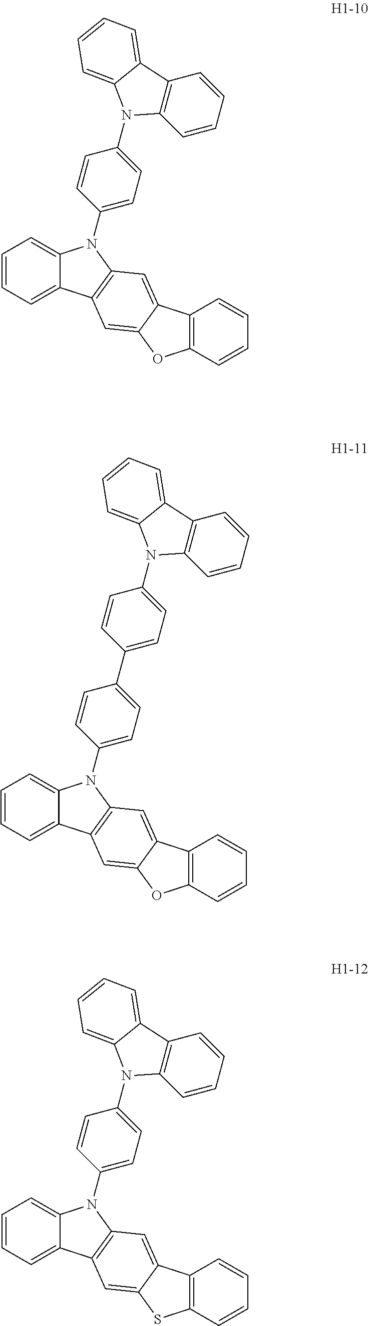 [SMILES: c1ccc2c(c1)oc1cc3c4ccccc4n(-c4ccc(-n5c6ccccc6c6ccccc65)cc4)c3cc12 ; c1ccc2c(c1)oc1cc3c4ccccc4n(-c4ccc(-c5ccc(-n6c7ccccc7c7ccccc76)cc5)cc4)c3cc12 ; c1ccc2c(c1)sc1cc3c4ccccc4n(-c4ccc(-n5c6ccccc6c6ccccc65)cc4)c3cc12]

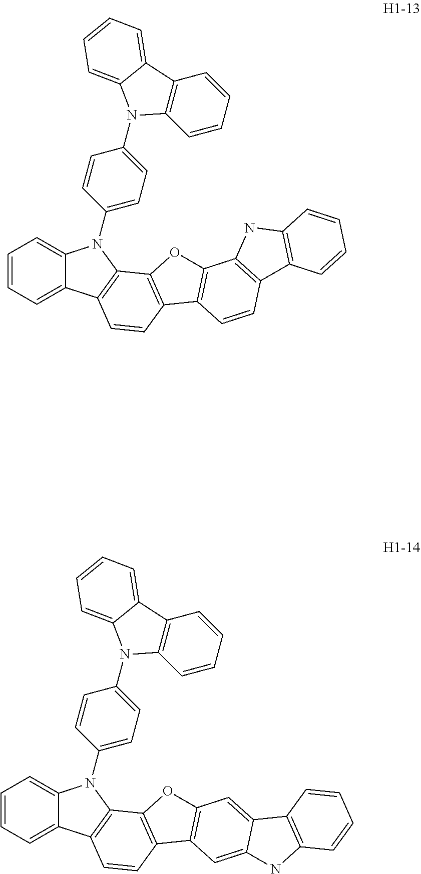 [SMILES: c1ccc2c(c1)[nH]c1c2ccc2c3ccc4c5ccccc5n(-c5ccc(-n6c7ccccc7c7ccccc76)cc5)c4c3oc21 ; c1ccc2c(c1)[nH]c1cc3c(cc12)oc1c3ccc2c3ccccc3n(-c3ccc(-n4c5ccccc5c5ccccc54)cc3)c21]

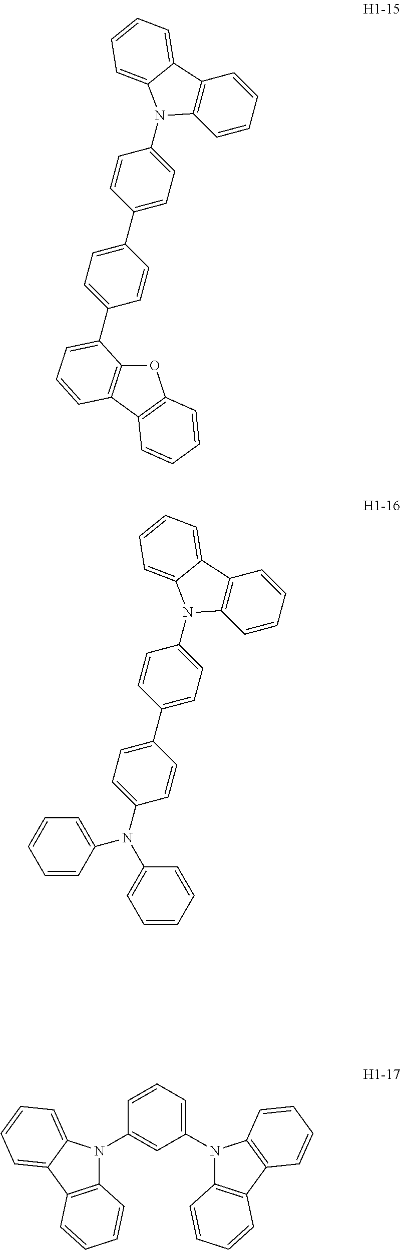 [SMILES: c1ccc2c(c1)oc1c(-c3ccc(-c4ccc(-n5c6ccccc6c6ccccc65)cc4)cc3)cccc12 ; c1ccc(N(c2ccccc2)c2ccc(-c3ccc(-n4c5ccccc5c5ccccc54)cc3)cc2)cc1 ; c1cc(-n2c3ccccc3c3ccccc32)cc(-n2c3ccccc3c3ccccc32)c1]

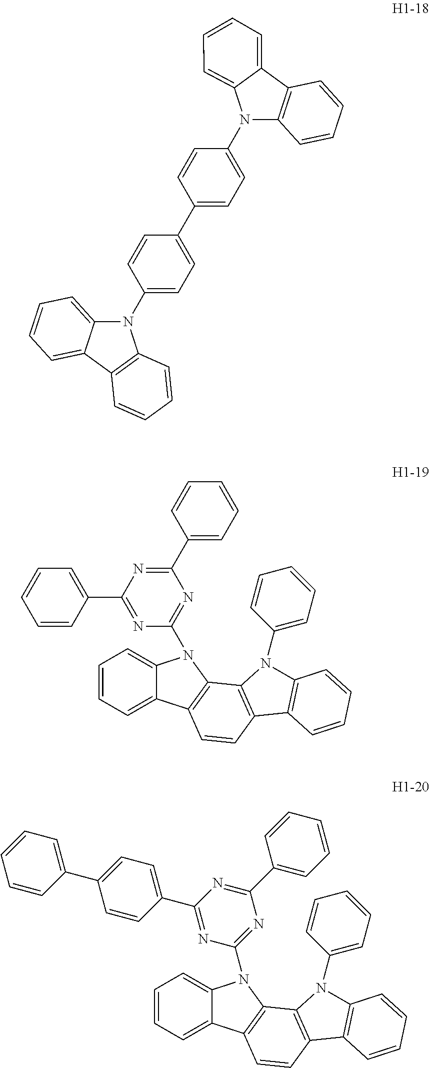 [SMILES: c1ccc2c(c1)c1ccccc1n2-c1ccc(-c2ccc(-n3c4ccccc4c4ccccc43)cc2)cc1 ; c1ccc(-c2nc(-c3ccccc3)nc(-n3c4ccccc4c4ccc5c6ccccc6n(-c6ccccc6)c5c43)n2)cc1 ; c1ccc(-c2ccc(-c3nc(-c4ccccc4)nc(-n4c5ccccc5c5ccc6c7ccccc7n(-c7ccccc7)c6c54)n3)cc2)cc1]

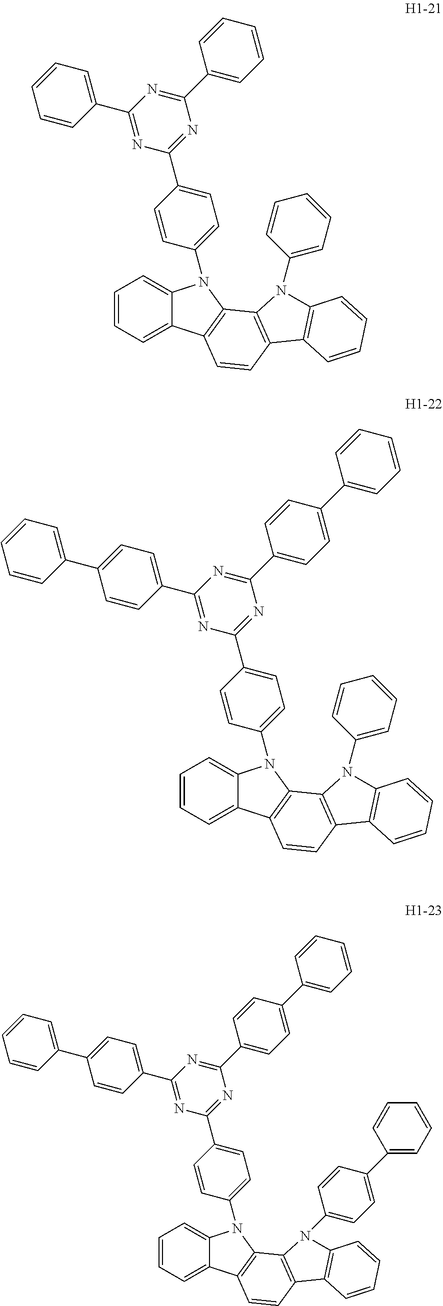 [SMILES: c1ccc(-c2nc(-c3ccccc3)nc(-c3ccc(-n4c5ccccc5c5ccc6c7ccccc7n(-c7ccccc7)c6c54)cc3)n2)cc1 ; c1ccc(-c2ccc(-c3nc(-c4ccc(-c5ccccc5)cc4)nc(-c4ccc(-n5c6ccccc6c6ccc7c8ccccc8n(-c8ccccc8)c7c65)cc4)n3)cc2)cc1 ; c1ccc(-c2ccc(-c3nc(-c4ccc(-c5ccccc5)cc4)nc(-c4ccc(-n5c6ccccc6c6ccc7c8ccccc8n(-c8ccc(-c9ccccc9)cc8)c7c65)cc4)n3)cc2)cc1]

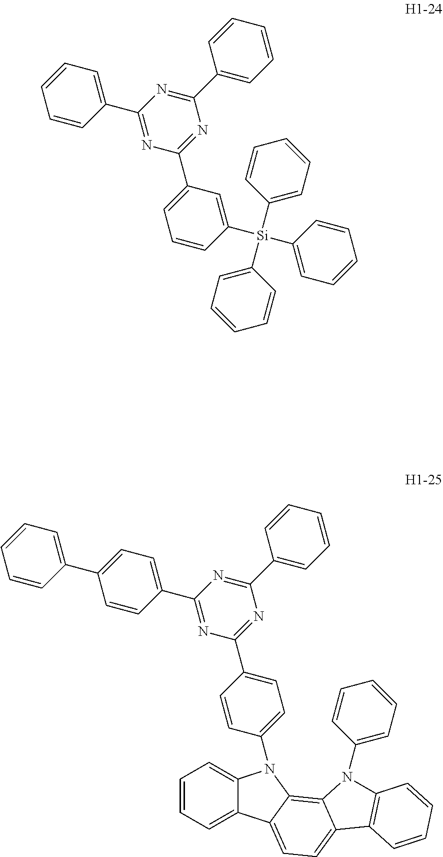 [SMILES: c1ccc(-c2nc(-c3ccccc3)nc(-c3cccc([Si](c4ccccc4)(c4ccccc4)c4ccccc4)c3)n2)cc1 ; c1ccc(-c2ccc(-c3nc(-c4ccccc4)nc(-c4ccc(-n5c6ccccc6c6ccc7c8ccccc8n(-c8ccccc8)c7c65)cc4)n3)cc2)cc1]

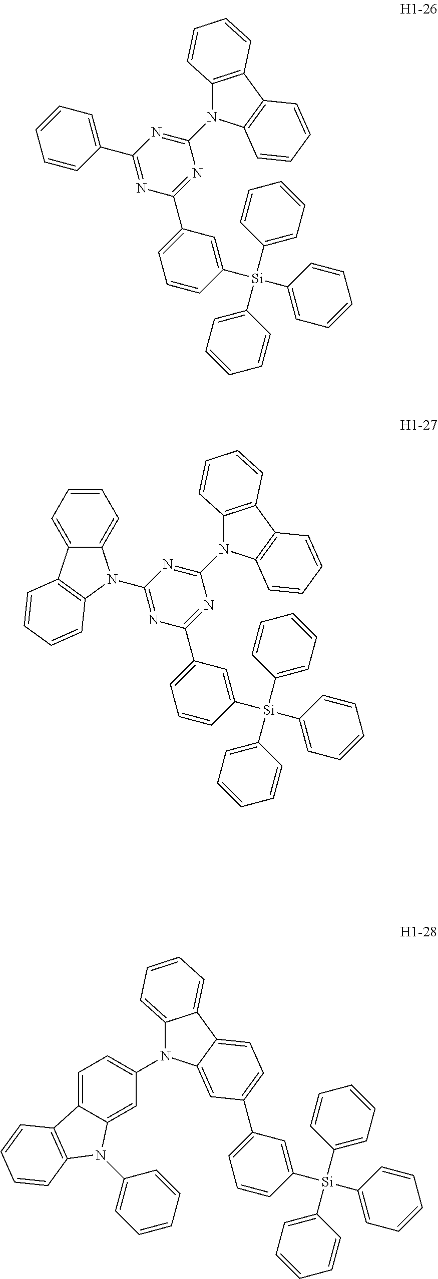 [SMILES: c1ccc(-c2nc(-c3cccc([Si](c4ccccc4)(c4ccccc4)c4ccccc4)c3)nc(-n3c4ccccc4c4ccccc43)n2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc(-n2c3ccccc3c3ccc(-n4c5ccccc5c5ccc(-c6cccc([Si](c7ccccc7)(c7ccccc7)c7ccccc7)c6)cc54)cc32)cc1]

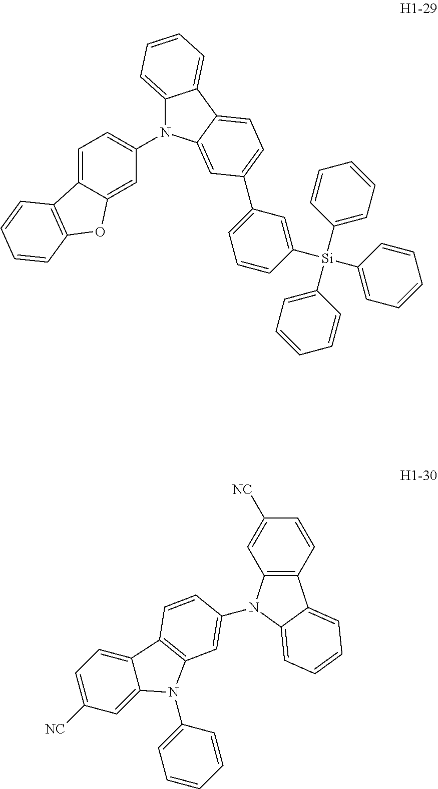 [SMILES: c1ccc([Si](c2ccccc2)(c2ccccc2)c2cccc(-c3ccc4c5ccccc5n(-c5ccc6c(c5)oc5ccccc56)c4c3)c2)cc1 ; N#Cc1ccc2c3ccccc3n(-c3ccc4c5ccc(C#N)cc5n(-c5ccccc5)c4c3)c2c1]

It will be noted that the structural formulas listed above are examples of the structure of the first host material H1 and are not limitations on the structure of the first host material H1. “H1-x” for the above structural formula is the name of each structural formula and is not part of the structure of the structural formula. X is a positive integer, and the same applies the following.

In some embodiments, the second host material H2 includes any one of the ligand groups VIA shown in the general formula VI.

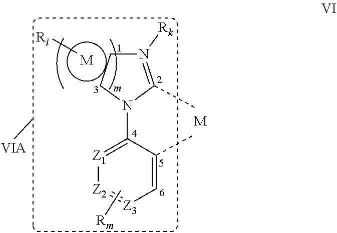

K is selected from a five-membered or six-membered carbocycle or a five-membered or six-membered carbon heterocycle; the value of m is selected from any one of 0, 1, 2, 3 and 4.

Z₁, Z₂ and Z₃ are the same or different, and are independently selected from carbon or nitrogen.

The ligand group VIA is bonded to M, and M is selected from one of ruthenium, osmium, iridium, palladium, copper, silver and gold; the second host material H2 includes n-dentate ligand material formed by the structure shown by the general formula VI and M, and n is selected from one of 3, 4, 5 and 6.

Rₖ, Rₘ and Rᵢ are the same or different, and are independently selected from any one of hydrogen, deuterium, halogen, alkyl, cycloalkyl, heteroalkyl, heterocycloalkyl, aralkyl, alkoxy, aryloxy, amino, silicyl, germyl, boryl, selenyl, alkenyl, cycloalkenyl, heteroalkenyl, alkynyl, aryl, heteroaryl, acyl, carboxylic acid, ether, ester, nitrile, isonitrile, sulfenyl, sulfinyl, sulfonyl, and phosphino.

Furthermore, at least one of Rₖ, Rₘ and Rᵢ contains deuterium. Since deuterium is heavy hydrogen, deuterium substitution is provided on carbon atoms or nitrogen atoms, which may increase the stability of chemical bonds, thereby improving the thermal stability of the second host material H2. It will be noted that at least one of Rₖ, Rₘ and Rᵢ contains deuterium, which means that at least one of Rₖ, Rₘ and Rᵢ is deuterium, or at least one of Rₖ, Rₘ and Rᵢ is any one of deuterium-containing alkyl, cycloalkyl, heteroalkyl, heterocycloalkyl, aralkyl, alkoxy, aryloxy, amino, silicyl, germyl, boryl, selenyl, alkenyl, cycloalkenyl, heteroalkenyl, alkynyl, aryl, heteroaryl, acyl, carboxylic acid, ether, ester, nitrile, isonitrile, sulfenyl, sulfinyl, sulfonyl, and phosphino.

It will be noted that the value of m is selected from one of 0, 1, 2, 3 and 4. That is, in a case of m=0, K does not exist, and the five-membered carbon heterocycle formed by the carbons at positions 1, 2, and 3 and nitrogen does not form a fused ring; in a case of m=1, the five-membered carbon heterocycle formed by the carbons at positions 1, 2, and 3 and nitrogen, together with one K, form a fused ring, and K is selected from a five-membered or six-membered carbocycles or carbon heterocycle; in a case of m=2, a five-membered carbon heterocycle formed by the carbons at positions 1, 2 and 3 and nitrogen, together with two K, form a fused ring, and the two K are the same or different and are independently selected from five-membered or six-membered carbocycles or carboheterocycles; in a case of m=3, a five-membered carbon heterocycle formed by the carbons at positions 1, 2 and 3 and nitrogen, together with three K, form a fused ring, the three K are the same or different and are independently selected from five-membered or six-membered carbocycles or carboheterocycles; in a case of m=4, a five-membered carbon heterocycle formed by the carbons at positions 1, 2 and 3 and nitrogen, together with four K, form a fused ring, the four K are the same or different and are independently selected from five-membered or six-membered carbocycles or carboheterocycles.

It will be understood that the second host material H2 includes an n-dentate ligand material formed by the structure shown by the general formula VI and M, where the value of n is selected from any of 3, 4, 5 and 6; that is, the ligand group VIA occupies the first dentate site and the second dentate site of the n-dentate ligand material, and the third dentate site, . . . , and the n-th dentate site of the n-dentate ligand material are occupied by other ligand groups, and the structures of the ligand groups occupying the third dentate site, . . . , and the n-th dentate site of the n-dentate ligand material are not limited in the present disclosure.

It will be noted that the position of Rₘ shown in the general formula VI means that Rₘ may be bonded to any one of the carbon at position 6, Z₁, Z₂ and Z₃; that is, Rₘ may be bonded to any element having a substitution position on the six-membered ring formed by the carbon at positions 4, 5, 6, and Z₁, Z₂, and Z₃. For the description of Rᵢ, reference may be made to the above description of Rₘ and will not be repeated here.

The ligand group VIA of the second host material H2 contains a carbene group (i.e., the five-membered carboheterocycle formed by carbons at positions 1, 2, and 3 and nitrogen), and the group may realize the emission of short-wavelength light, and the color of the short-wavelength light is, for example, dark blue. Moreover, the second host material H2 may be compatible with the manufacturing process of the light-emitting device 100 in the related arts, such as evaporation, which reduces the manufacturing cost of the light-emitting device 100.

In some embodiments, the second host material H2 is selected from any of structures shown in the following general formula VII.

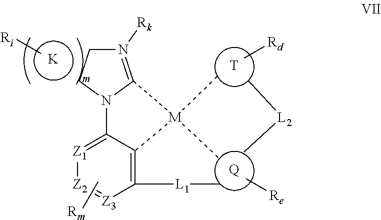

K is selected from a five-membered or six-membered carbocycle or a five-membered or six-membered carbon heterocycle; the value of m is selected from any one of 0, 1, 2, 3 and 4.

T and Q are the same or different, and are independently selected from five-membered or six-membered carbocycles or carboheterocycles.

Z₁, Z₂ and Z₃ are the same or different, and are independently selected from carbon or nitrogen.

M is selected from platinum or palladium.

L₁ and L₂ are the same or different, and are independently selected from any one of B(Rf), N(Rf), P(Rf), O, S, Se, C═O, S═O, SO₂, C(Rf Rg), Si(Rf Rg) and Ge(Rf Rg).

Rₖ, Rₘ, Rᵢ, Rₑ, R_{d}, Rf, and Rg are the same or different, and are independently selected from any of hydrogen, deuterium, halogen, alkyl, cycloalkyl, heteroalkyl, heterocycloalkyl, aralkyl, alkoxy, aryloxy, amino, silicyl, germyl, boryl, selenyl, alkenyl, cycloalkenyl, heteroalkenyl, alkynyl, aryl, heteroaryl, acyl, carboxylic acid, ether, ester, nitrile, isonitrile, sulfenyl, sulfinyl, sulfonyl, and phosphino.

Furthermore, L₁ is different from L₂, and at least one of Rₖ, Rₘ and Rᵢ contains deuterium. Since deuterium is heavy hydrogen, deuterium substitution is provided on carbon atoms or nitrogen atoms, which may increase the stability of chemical bonds, thereby improving the thermal stability of the second host material H2. It will be noted that at least one of Rₖ, Rₘ and Rᵢ contains deuterium, which means that at least one of Rₖ, Rₘ and Rᵢ is deuterium, or at least one of Rₖ, Rₘ and Rᵢ is any one of deuterium-containing alkyl, cycloalkyl, heteroalkyl, heterocycloalkyl, aralkyl, alkoxy, aryloxy, amino, silicyl, germyl, boryl, selenyl, alkenyl, cycloalkenyl, heteroalkenyl, alkynyl, aryl, heteroaryl, acyl, carboxylic acid, ether, ester, nitrile, isonitrile, sulfenyl, sulfinyl, sulfonyl, and phosphino.

It will be noted that, L₁ and L₂ are independently selected from any one of B(Rf), N(Rf), P(Rf), O, S, Se, C═O, S═O, SO₂, C(Rf Rg), Si(Rf Rg) and Ge(Rf Rg). B(Rf) is substituted or unsubstituted boron; N(Rf) is substituted or unsubstituted nitrogen; P(Rf) is substituted or unsubstituted phosphorus; O is oxygen; S is sulfur; Se is selenium; C═O is carbonyl; S═O is thionyl; SO₂ is sulfuryl; C(Rf Rg) is substituted or unsubstituted carbon; Si(Rf Rg) is substituted or unsubstituted silicon; Ge(Rf Rg) is substituted or unsubstituted germanium.

It will be noted that the description of m here may refer to the above description of m, and the description of Rₘ, Rᵢ, Rₑ, R_{d}, and Rf may refer to the above description of Rₘ, which will not be repeated here.

In some embodiments, T and Q are not both five-membered carbocycles or carboheterocycles, which is due to a fact that in a case where T and Q are both the five-membered carbocycles or carboheterocycles, the stability of the formed compound is relatively poor. By setting T and Q not to both be five-membered carbocycle or carboheterocycle, it is possible to improve the stability of the second host material H2.

For example, in a case where M is platinum, the structural formula of the second host material H2 may be as follows.

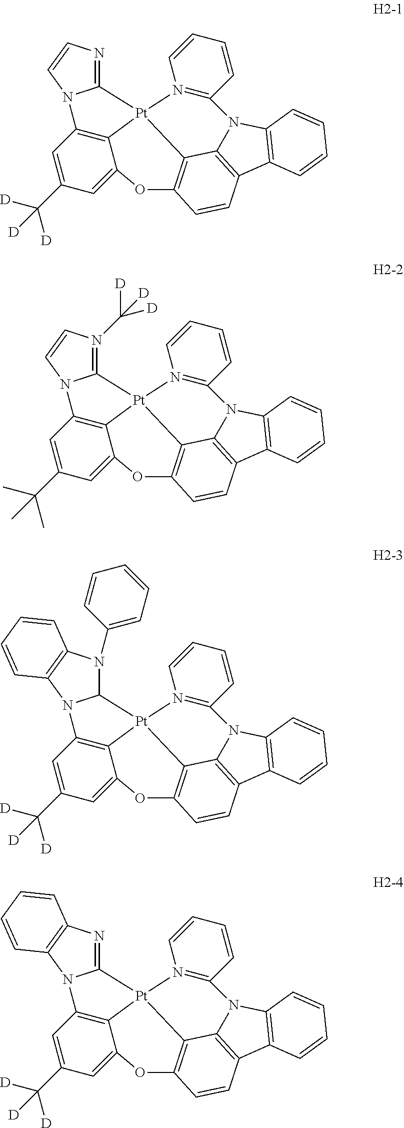

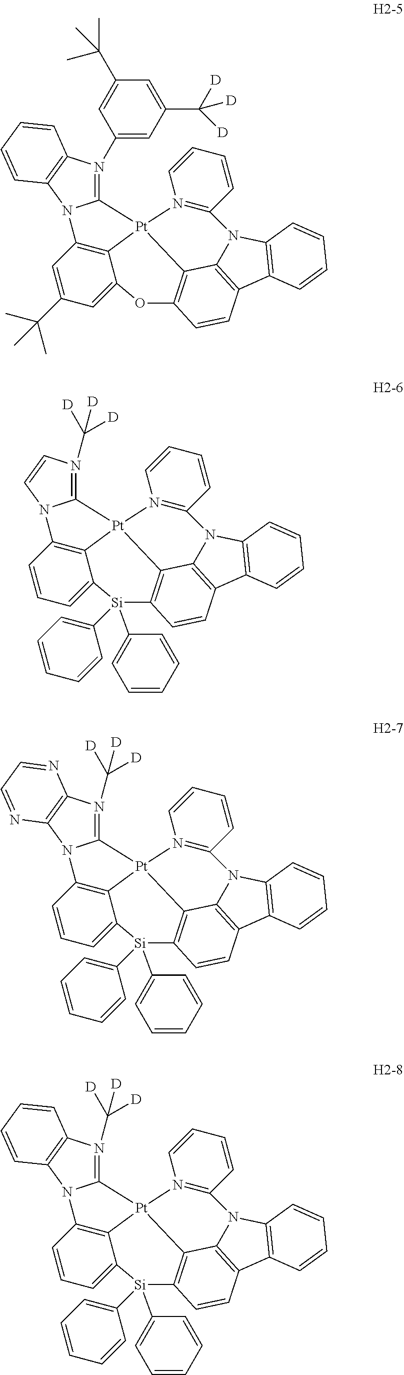

It will be noted that the structural formulas listed above are examples of the structure of the second host material H2 and are not limitations on the structure of the second host material H2. “H2-x” for the above structural formula is the name of each structural formula and is not part of the structure of the structural formula, where X is a positive integer; the same applies the following.

In some other embodiments, the second host material H2 is a delayed fluorescent material, which is selected from any one of the structures shown in the following general formula VIII.

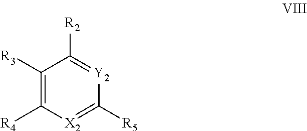

X₂ and Y₂ are the same or different, and are independently selected from carbon or nitrogen.

R₂, R₃, R₄ and R₅ are the same or different, and are independently selected from a substituted or unsubstituted substituent group VIIIA or substituted or unsubstituted substituent group VIIIB; R₂, R₃, R₄ and R₅ together contain at least two substituted or unsubstituted substituent group VIIIA, and at least one substituted or unsubstituted substituent group VIIIB.

The substituent group VIIIA is selected from any one of VIIIA-a to VIIIA-i.

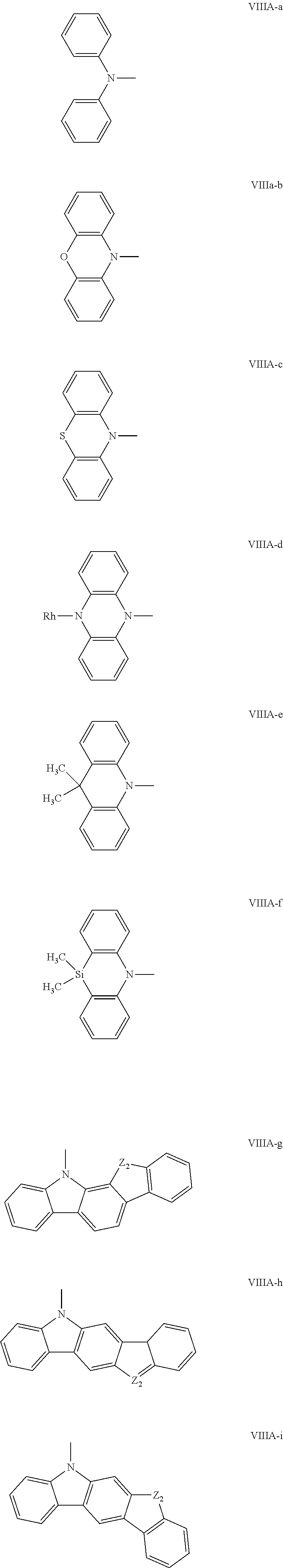

Z₂ is selected from any one of carbon, nitrogen, oxygen and sulfur.

Rh is selected from any one of hydrogen, deuterium, halogen, alkyl, cycloalkyl, heteroalkyl, heterocycloalkyl, aralkyl, alkoxy, aryloxy, amino, silicyl, germyl, boryl, selenyl, alkenyl, cycloalkenyl, heteroalkenyl, alkynyl, aryl, heteroaryl, acyl, carboxylic acid, ether, ester, nitrile, isonitrile, sulfenyl, sulfinyl, sulfonyl, and phosphino.

The substituent group VIIIB is selected from any one of VIIIB-a to VIIIB-j.

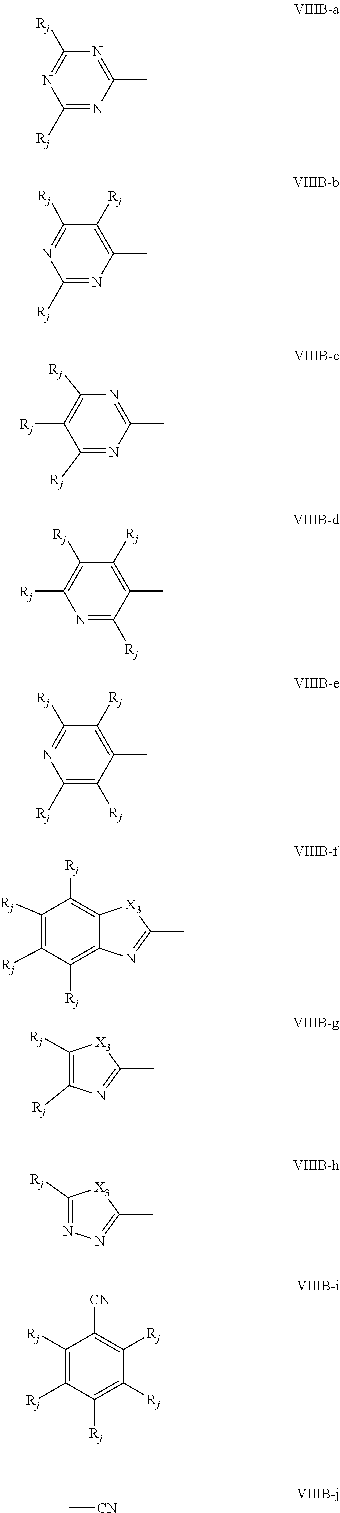

X₃ is selected from oxygen or sulfur.

Rj is selected from any one of hydrogen, deuterium, halogen, nitrile, substituted or unsubstituted alkyl, substituted or unsubstituted haloalkyl, substituted or unsubstituted alkoxy, substituted or unsubstituted haloalkoxy, substituted or unsubstituted aryl, substituted or unsubstituted haloaryl, substituted or unsubstituted silyl and substituted or unsubstituted heterocycle.

It will be noted that the two benzene rings in VIIIA-a may be bonded by single bonds to form substituted or unsubstituted VIIIA-a-1, and the structural formula of which may be as shown in the following formula.

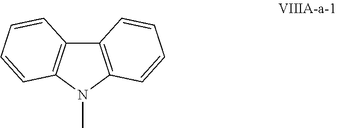

It will be noted that the structural formulas listed above are examples of the structures of substituent group VIIIA and substituent group VIIIB, and are not limitations on the structures of substituent group VIIIA and substituent group VIIIB. “VIIIA-x” and “VIIIB-x” for the above structural formula are the name of each structural formula and are not part of the structure of the structural formula.

Moreover, the second host material H2 selected from the structures shown in general formula VIII may be compatible with the manufacturing process of the light-emitting device 100 in the related arts, such as evaporation, which reduces the manufacturing cost of the light-emitting device 100.

For example, in a case where X₂ and Y₂ are substituted or unsubstituted carbons, the structural formula of the second host material H2 may be as shown in the following formula.

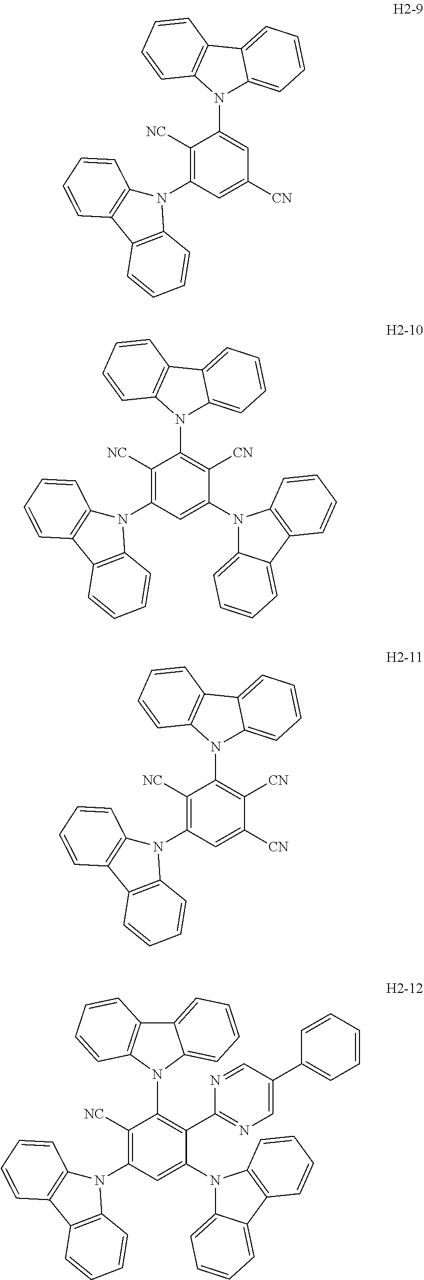

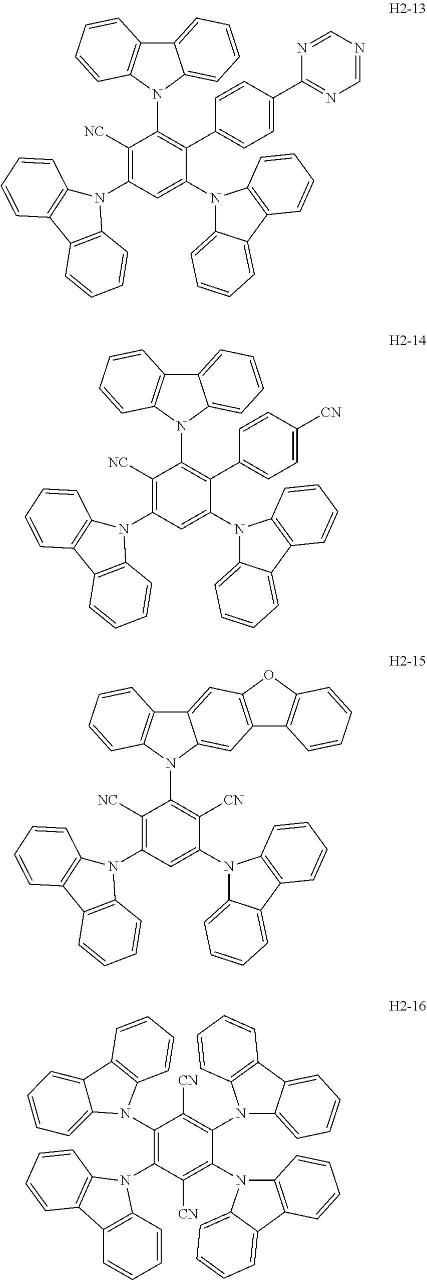 [SMILES: N#Cc1c(-n2c3ccccc3c3ccccc32)cc(-n2c3ccccc3c3ccccc32)c(-c2ccc(-c3ncncn3)cc2)c1-n1c2ccccc2c2ccccc21 ; N#Cc1ccc(-c2c(-n3c4ccccc4c4ccccc43)cc(-n3c4ccccc4c4ccccc43)c(C#N)c2-n2c3ccccc3c3ccccc32)cc1 ; N#Cc1c(-n2c3ccccc3c3ccccc32)cc(-n2c3ccccc3c3ccccc32)c(C#N)c1-n1c2ccccc2c2cc3oc4ccccc4c3cc21 ; N#Cc1c(-n2c3ccccc3c3ccccc32)c(-n2c3ccccc3c3ccccc32)c(C#N)c(-n2c3ccccc3c3ccccc32)c1-n1c2ccccc2c2ccccc21]

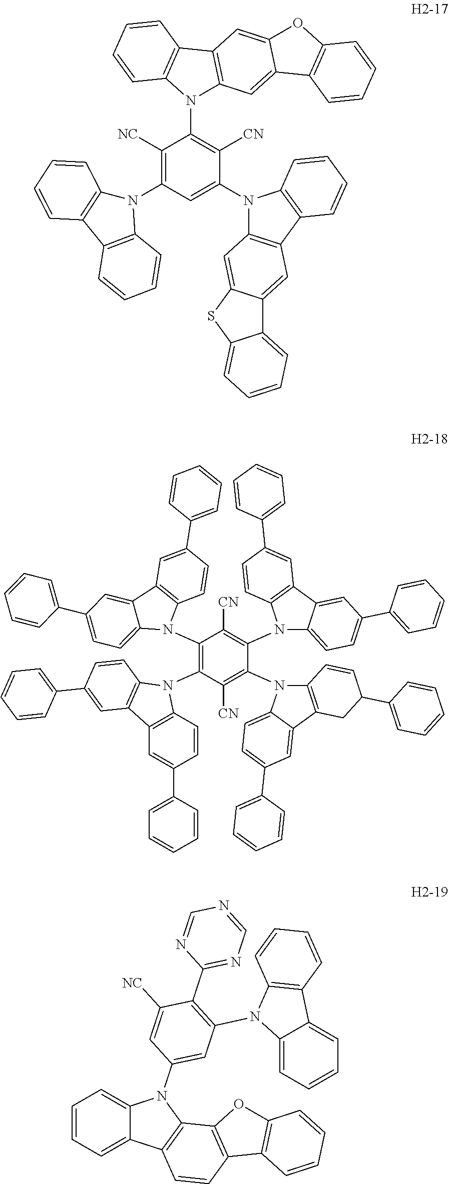 [SMILES: N#Cc1c(-n2c3ccccc3c3ccccc32)cc(-n2c3ccccc3c3cc4c(cc32)sc2ccccc24)c(C#N)c1-n1c2ccccc2c2cc3oc4ccccc4c3cc21 ; N#Cc1c(-n2c3c(c4cc(-c5ccccc5)ccc42)CC(c2ccccc2)C=C3)c(-n2c3ccc(-c4ccccc4)cc3c3cc(-c4ccccc4)ccc32)c(C#N)c(-n2c3ccc(-c4ccccc4)cc3c3cc(-c4ccccc4)ccc32)c1-n1c2ccc(-c3ccccc3)cc2c2cc(-c3ccccc3)ccc21 ; N#Cc1cc(-n2c3ccccc3c3ccc4c5ccccc5oc4c32)cc(-n2c3ccccc3c3ccccc32)c1-c1ncncn1]

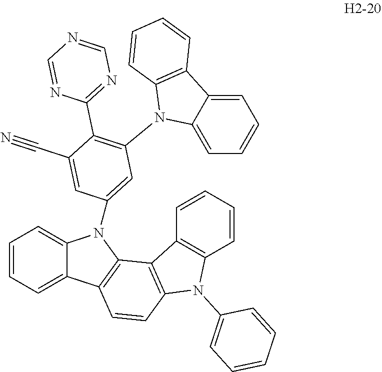 [SMILES: N#Cc1cc(-n2c3ccccc3c3ccc4c(c5ccccc5n4-c4ccccc4)c32)cc(-n2c3ccccc3c3ccccc32)c1-c1ncncn1]

It will be noted that the structural formulas listed above are examples of the structure of the second host material H2 and are not limitations on the structure of the second host material H2. “H2-x” for the above structural formula is the name of each structural formula and is not part of the structure of the structural formula, where x is a positive integer; the same applies the following.

In some embodiments, the first light-emitting material D1 is selected from the structures represented by the following general formula I.

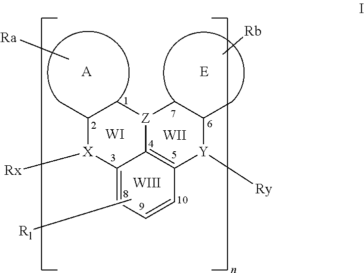

X, Y and Z are the same or different, and are independently selected from any of C(Re), N, B, P, P═O, Si(Re), S and a single bond; a value of n is selected from any of 1, 2, 3 and 4.

A and E are the same or different, and are independently selected from any one of five-membered or six-membered carbocycles, five-membered or six-membered carboheterocycles, and a fused ring.

Ra, Rb, Rx, Ry, R₁ and Re are the same or different, and are independently selected from any of hydrogen, deuterium, cyano, substituted or unsubstituted C5-C50 aryl, and substituted or unsubstituted C1-C50 alkyl.

It will be noted that X, Y and Z are independently selected from any one of C(Re), N, B, P, P═O, Si(Re), S and a single bond. C(Re) is substituted or unsubstituted carbon; N is nitrogen; B is boron; P is phosphorus; P═O is phosphoryl; Si(Re) is substituted or unsubstituted silicon; S is sulfur; the single bond means that in a case where X, Y or Z does not exist, the elements attached to X, Y or Z are directly bonded to each other by a covalent bond; specifically, in a case where X is a single bond, the carbon at position 2 is bonded to the carbon at position 3 by a covalent bond, and Rx does not exist; in a case where Y is a single bond, the carbon at Position 5 is directly bonded to the carbon at position 6 by a covalent bond, and Ry does not exist; in a case where Z is a single bond, the carbon at position 1 is directly bonded to the carbon at position 4 by a covalent bond, and the carbon at position 4 is directly bonded to the carbon at position 7 by a covalent bond.

For the convenience of description, the ring formed by the carbons at positions 1, 2, 3, and 4 and X and Z is referred to as WI, the ring formed by the carbons at positions 4, 5, 6, and 7 and Y and Z is referred to as WII, and the ring formed by the carbons at positions 3, 4, 5, 6, 8, 9, and 10 is referred to as WIII.

It will be noted that the value of n is selected from any one of 1, 2, 3 and 4. That is, in a case of n=1, in the structure of the first light-emitting material D1, the number of E is one, and the number of fused rings formed by A, WI, WII, and Will is one; in a case of n=2, in the structure of the first light-emitting material D1, the number of E is one, the number of fused rings formed by A, WI, WII, and Will is two, and the two fused rings are bonded by the E; in a case of n=3, in the structure of the first light-emitting material D1, the number of E is one or two, the number of fused rings formed by A, WI, WII, and Will is three, and the three fused rings are bonded by one or two E; in a case of n=4, in the structure of the first light-emitting material D1, the number of E is one, two or three, the number of fused rings formed by A, WI, WII, WIII is four, and the four fused rings are bonded by the above one, two, or three E.

It will be noted that the position of R₁ shown in general formula I means that R₁ may be bonded to any element with a substitution on WIII; that is, R₁ may be bonded to any carbon having a substitution position of the carbons at positions 3, 4, 5, 6, 8, 9, 10. For the description of Ra and Rb, reference may be made to the above description of R₁, and will not be repeated here.

It will be noted that the “Cx” aryl refers to an aryl group having x carbon (C) atoms; the aryl may be phenyl, heteroaryl, furyl, pyranyl, thienyl, pyridyl, or the like; the “Cx” alkyl refers to an alkyl group having x carbon (C) atoms, where x is a positive integer; the same applies the following.

The first light-emitting material D1 contains groups X—Y—Z with the light-emitting function, which may emit light from blue light to red light. The color of the light emitted by the first light-emitting material D1 is related to the structural characteristics of the first light-emitting material D1. The above structural characteristics include but are not limited to the type of substituent, the position of the substituent, and the value of n.

In some embodiments, the first light-emitting material D1 is selected from the structures represented by the following general formula II.

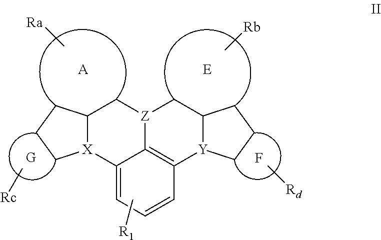

X, Y and Z are independently selected from any of C(Re), N, B, P, P═O, Si(Re), S and a single bond; and Z is different from X and Y.

A, E, F and G are the same or different, and are independently selected from any of five-membered or six-membered carbocycles, five-membered or six-membered carboheterocycles and a fused ring, and A, E, F and G are not all the six-membered carbocycles; in a case where G is a six-membered carbocycle, F is not a six-membered carbocycle or does not exist.

Ra, Rb, Rc, Rd, R₁ and Re are the same or different, and are independently selected from any of hydrogen, deuterium, cyano, substituted or unsubstituted C5-C50 aryl, and substituted or unsubstituted C1-C50 alkyl.

It will be noted that, for the description of C(Re), N, B, P, P═O, Si(Re), S and the single bond, reference may be made to the above description of C(Re), N, B, P, P═O, Si(Re), S and the single bond; for the description of Ra, Rb, Rc, Rd, and R₁, reference may be made to the above description of R₁; for the description of the Cx aryl and the Cx alkyl, reference may be made to the above description of the Cx aryl and the Cx alkyl, which will not be repeated here.

It will be understood that in the structure represented by the general formula I, n=1, Rx is fused with A, and Ry is fused with E; the structure represented by the general formula I may be transformed into the structure represented by the general formula II.

It will be noted that Z is different from X and Y, which means that Z is different from X, and Z is different from Y. There is no limit to whether X and Y are the same; that is, X and Y may be the same or different.

A, E, F and G are not all the six-membered carbocycles. In a case where A, E, F and G are all the six-membered carbocycles, the structure shown in the general formula II is a symmetrical structure, which increases the number of photons emitted by the first light-emitting material D1 at the triplet energy level. The relatively slow light emitting process at the triplet energy level will also lead to a great difference in the number of excitons under different current conditions, which is manifested as a large efficiency attenuation ΔE, resulting in display difference at the different gray scales. In the embodiments of the present disclosure, by setting A, E, F and G to not all be the six-membered carbocycles, the difference in the number of excitons under different current conditions may be reduced, thereby reducing the display difference at different gray scales.

It will be noted that in a case where G is a six-membered carbocycle, F is not a six-membered carbocycle or F does not exist, which means that in a case where G is a six-membered carbocycle, F is selected from any one of five-membered carbocycle, five-membered or six-membered carboheterocycle and a fused ring, or F does not exist.

For example, in a case where X and Y are nitrogen, Z is boron, A, E, G are each a six-membered carbocycle, F is a six-membered carboheterocycle, and Ra and Rc are each C4 alkyl, the structural formula of the first light-emitting material D1 may be as follows.

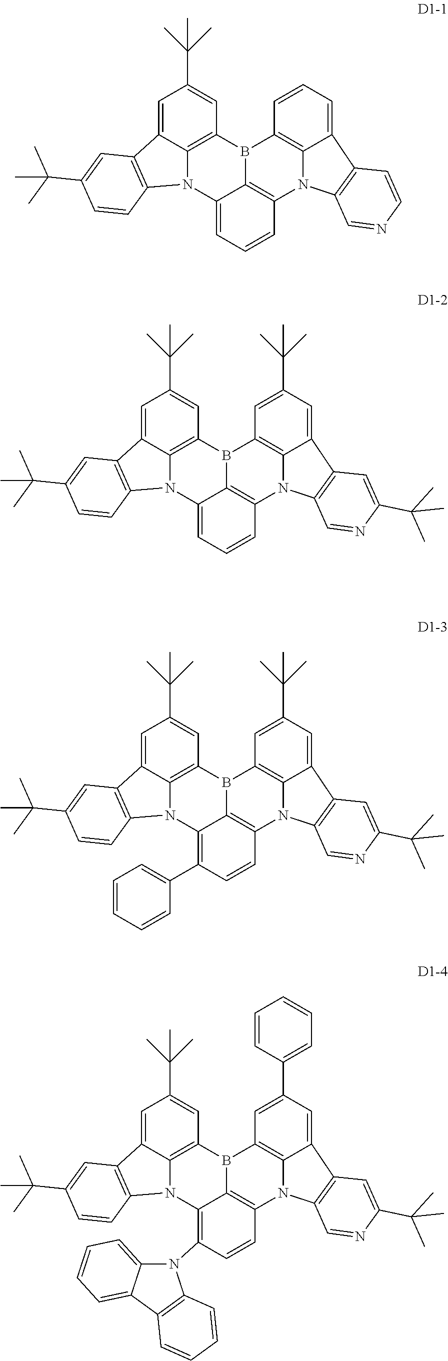

For example, in a case where X and Y are nitrogen, Z is boron, A, E, G are each a six-membered carbocycle, F does not exist, and Ra and Rc are each C4 alkyl, the structural formula of the first light-emitting material D1 may be as follows.

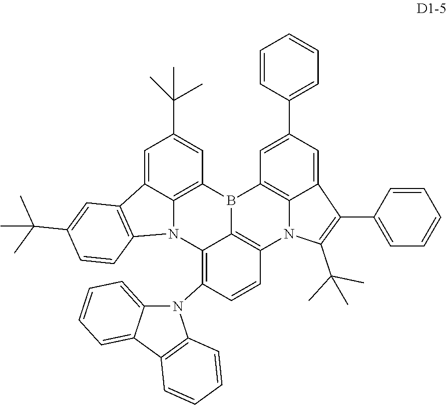 [SMILES: CC(C)(C)c1ccc2c(c1)c1cc(C(C)(C)C)cc3c1n2-c1c(-n2c4ccccc4c4ccccc42)ccc2c1B3c1cc(-c3ccccc3)cc3c(-c4ccccc4)c(C(C)(C)C)n-2c13]

For example, in a case where X and Y are nitrogen, Z is boron, A and G are each a six-membered carbocycle, E is

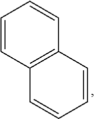

F does not exist, Ra is a benzene ring, and Rc is C4 alkyl, the structural formula of the first light-emitting material D1 may be as follows.

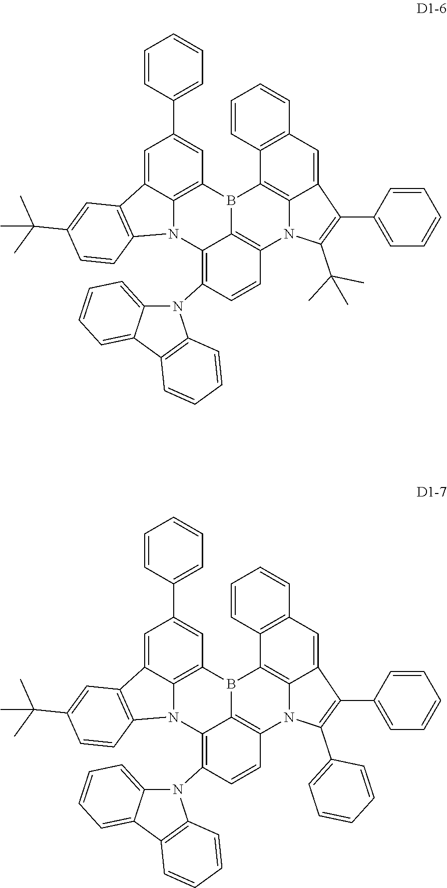 [SMILES: CC(C)(C)c1ccc2c(c1)c1cc(-c3ccccc3)cc3c1n2-c1c(-n2c4ccccc4c4ccccc42)ccc2c1B3c1c3ccccc3cc3c(-c4ccccc4)c(C(C)(C)C)n-2c13 ; CC(C)(C)c1ccc2c(c1)c1cc(-c3ccccc3)cc3c1n2-c1c(-n2c4ccccc4c4ccccc42)ccc2c1B3c1c3ccccc3cc3c(-c4ccccc4)c(-c4ccccc4)n-2c13]

For example, in a case where X and Y are nitrogen. Z is boron, A and G are each a six-membered carbocycle, E is

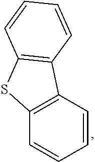 [SMILES: c1ccc2c(c1)sc1ccccc12]

F does not exist, and Ra and Rc are each C4 alkyl, the structural formula of the first light-emitting material D1 may be as follows.

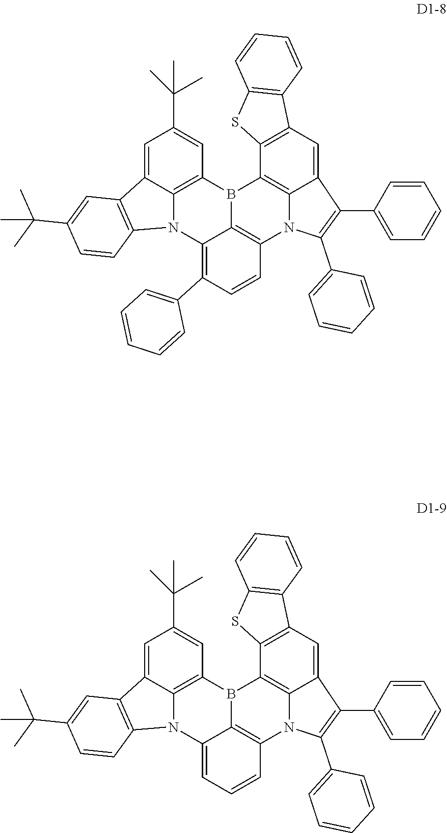 [SMILES: CC(C)(C)c1ccc2c(c1)c1cc(C(C)(C)C)cc3c1n2-c1c(-c2ccccc2)ccc2c1B3c1c3sc4ccccc4c3cc3c(-c4ccccc4)c(-c4ccccc4)n-2c13 ; CC(C)(C)c1ccc2c(c1)c1cc(C(C)(C)C)cc3c1n2-c1cccc2c1B3c1c3sc4ccccc4c3cc3c(-c4ccccc4)c(-c4ccccc4)n-2c13]

For example, in a case where X and Y are nitrogen, Z is boron, A and G are each a six-membered carbocycle, E is

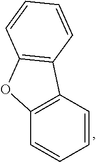 [SMILES: c1ccc2c(c1)oc1ccccc12]

F does not exist, and Ra and Rc are each C4 alkyl, the structural formula of the first light-emitting material D1 may be as follows.

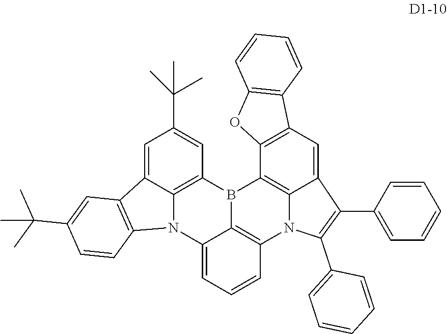 [SMILES: CC(C)(C)c1ccc2c(c1)c1cc(C(C)(C)C)cc3c1n2-c1cccc2c1B3c1c3oc4ccccc4c3cc3c(-c4ccccc4)c(-c4ccccc4)n-2c13]

It will be noted that the structural formulas listed above are examples of the structure of the first light-emitting material D1 and are not limitations on the structure of the first light-emitting material D1. “D1-x” for the above structural formula is the name of each structural formula and is not part of the structure of the structural formula, where x is a positive integer, and the same applies the following.

In some embodiments, the first light-emitting material D1 is selected from the structures represented by the following general formula III.

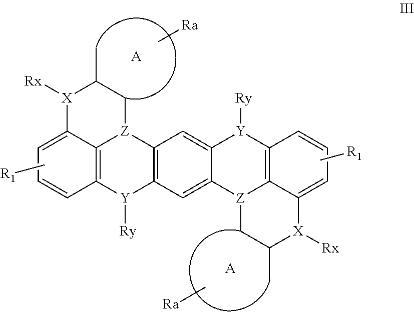

X, Y and Z are independently selected from any one of C(Re), N, B, P, P═O, Si(Re), S and a single bond; X and Y are the same or different, and Z is different from X and Y.

A is selected from five-membered or six-membered carbocycle, or five-membered or six-membered carboheterocycle.

Ra, Rx, Ry, R₁ and Re are the same or different, and are independently selected from any of hydrogen, deuterium, cyano, substituted or unsubstituted C5-C50 aryl, and substituted or unsubstituted C1-C50 alkyl.

It will be noted that, for the description of C(Re), N, B, P, P═O, Si(Re), S and the single bond, reference may be made to the above description of C(Re), N, B, P, P═O, Si(Re), S and the single bond; for the description of Ra and R₁, reference may be made to the above description of R₁; for the description of the Cx aryl and the Cx alkyl, reference may be made to the above description of the Cx aryl and the Cx alkyl, which will not be repeated here.

It will be understood that in the structure shown in the general formula I, the number of E is one, and E is a six-membered carbocycle, Rb is hydrogen, and n=2, i.e., the number of fused rings formed by A, WI, WII, and Will is two, and the two fused rings are bonded by the E, the structure shown in the general formula I may be transformed into the structure shown in the general formula III.

It will be noted that Z is different from X and Y, which means that Z is different from X, and Z is different from Y.

For example, in a case where X is a single bond, Y is boron, Z is nitrogen, A is a six-membered carbocycle, and Rx does not exist, the structural formula of the first light-emitting material D1 may be as follows.

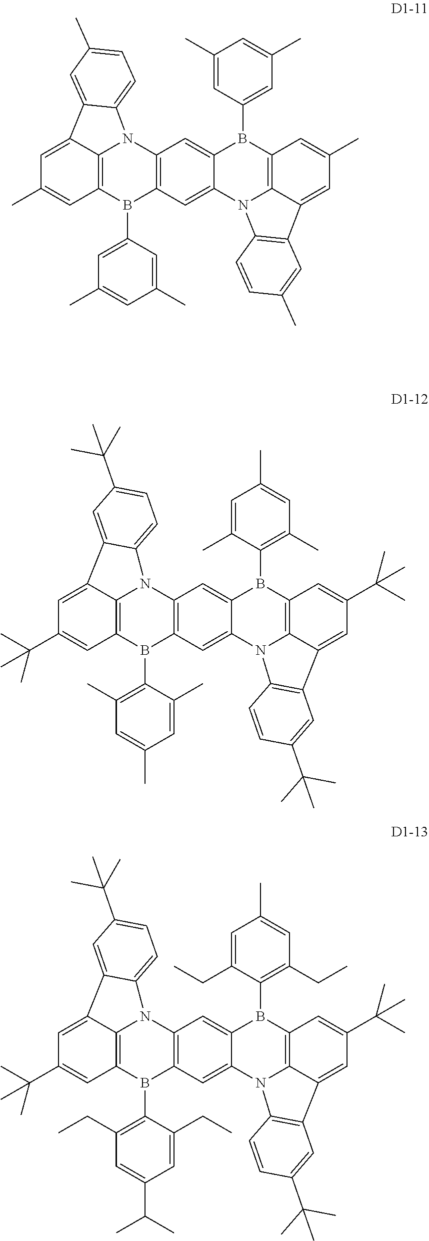

For example, in a case where X is oxygen, Y is boron, Z is nitrogen, A is a six-membered carbocycle, Rx does not exist, R₁ and Ra are each hydrogen, and Ry is C6 aryl, the structural formula of the first light-emitting material D1 may be as follows.

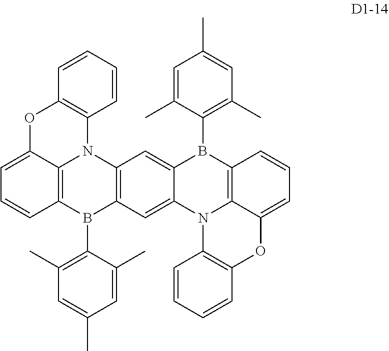 [SMILES: Cc1cc(C)c(B2c3cc4c(cc3N3c5ccccc5Oc5cccc2c53)B(c2c(C)cc(C)cc2C)c2cccc3c2N4c2ccccc2O3)c(C)c1]

For example, in a case where X is silicon, Y is boron, Z is nitrogen, A is a six-membered carbocycle, Rx is a benzene ring, R₁ and Ra are each hydrogen, and Ry is C6 aryl, the structural formula of the first light-emitting material D1 may be as follows.

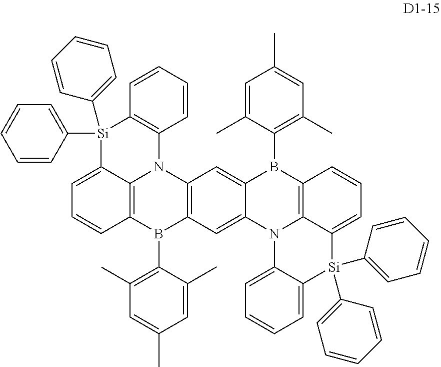 [SMILES: Cc1cc(C)c(B2c3cc4c(cc3N3c5ccccc5[Si](c5ccccc5)(c5ccccc5)c5cccc2c53)B(c2c(C)cc(C)cc2C)c2cccc3c2N4c2ccccc2[Si]3(c2ccccc2)c2ccccc2)c(C)c1]

It will be noted that the structural formulas listed above are examples of the structure of the first light-emitting material D1 and are not limitations on the structure of the first light-emitting material D1. “D1-x” for the above structural formula is the name of each structural formula and is not part of the structure of the structural formula, where x is a positive integer, and the same applies the following.

In some embodiments, the first light-emitting material D1 is selected from the structures represented by the following general formula IV.

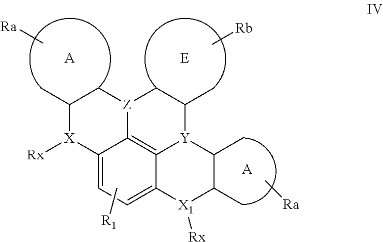

X, Y, Z and X₁ are independently selected from any one of C(Re), N, B, P, P═O, Si(Re), S and a single bond, and in a case where Z and Y are the same, X and X₁ are the same; in a case where Z is different from Y, X is different from X₁.

A and E are the same or different, and are independently selected from five-membered or six-membered carbocycles or carboheterocycles; A and E are not all six-membered carbocycles.

Ra, Rb, Rx, R₁ and Re are the same or different, and are independently selected from any of hydrogen, deuterium, cyano, substituted or unsubstituted C5-C50 aryl, and substituted or unsubstituted C1-C50 alkyl.

It will be noted that, for the description of C(Re), N, B, P, P═O, Si(Re), S and the single bond, reference may be made to the above description of C(Re), N, B, P, P═O, Si(Re), S and the single bond; for the description of Ra, Rb and R₁, reference may be made to the above description of R₁; for the description of the Cx aryl and the Cx alkyl, reference may be made to the above description of the Cx aryl and the Cx alkyl, which will not be repeated here.

It will be understood that in the structure shown in the general formula I, there is one E and multiple number of R₁, and one R₁ is fused to Ry, and thus, the structure shown in the general formula I may be transformed into the structure shown in the general formula IV. The first light-emitting material D1 is selected from any one of the structures represented by the general formula IV. Thus, the number of positions that capable of undergoing fusion in the first light-emitting material D1 is increased, which may increase the resonance effect.

It will be noted that in the structure shown in the general formula IV, Z and Y are not both the boron. In a case where Z and Y are both boron, it is possible to affect the formation of the resonance structure, thereby affecting the luminous performance of the first light-emitting material D1. In the embodiments of the present disclosure, Z and Y are not both boron, so that the first light-emitting material D1 may reliably realize the light-emitting function.

In some embodiments, the first light-emitting material D1 is selected from any one of the structures represented by the following general formula V.

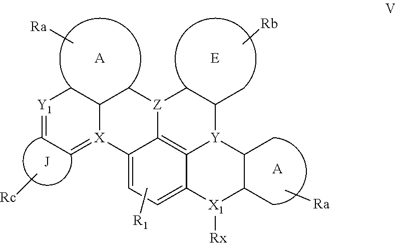

X, Y, Z, X₁ and Y₁ are independently selected from any one of C(Re), N, B, P, P═O, Si(Re), S and a single bond; in a case where Z is the same as Y, X is the same as X₁; in a case where Z is different from Y, X is different from X₁, and Y₁ is different from X.

A, E, and J are the same or different, and are independently selected from five-membered or six-membered carbocycles or carboheterocycles, and A, E, and J are not all six-membered carbocycles.

Ra, Rb, Rc, Rx, R₁ and Re are the same or different, and are independently selected from any of hydrogen, deuterium, cyano, substituted or unsubstituted C5-C50 aryl, and substituted or unsubstituted C1-C50 alkyl.

It will be noted that, for the description of C(Re), N, B, P, P═O, Si(Re), S and the single bond, reference may be made to the above description of C(Re), N, B, P, P═O, Si(Re), S and the single bond; for the description of Ra, Rb, Rc, and R₁, reference may be made to the above description of R₁; for the description of the Cx aryl and the Cx alkyl, reference may be made to the above description of the Cx aryl and the Cx alkyl, which will not be repeated here.

It will be understood that in the structure represented by the general formula IV, in a case where Ra that is adjacent to Z is fused to Rx that is adjacent to X, the structure represented by the general formula IV may be transformed into the structure represented by the general formula V. The first light-emitting material D1 is selected from any one of the structures represented by the general formula V. Thus, the number of positions that capable of undergoing fusion formed in the structure of the first light-emitting material D1 is increased, which may increase the resonance effect.

For example, in a case where X is nitrogen, Y is nitrogen, Z is boron, X₁ is boron, Y₁ is substituted boron, A, E, and J are all six-membered carbocycles, Rb is hydrogen, R₁, Ra, and Rc are all C4 alkyl, and Rx is substituted C6 aryl, the structural formula of the first light-emitting material D1 may be as follows.

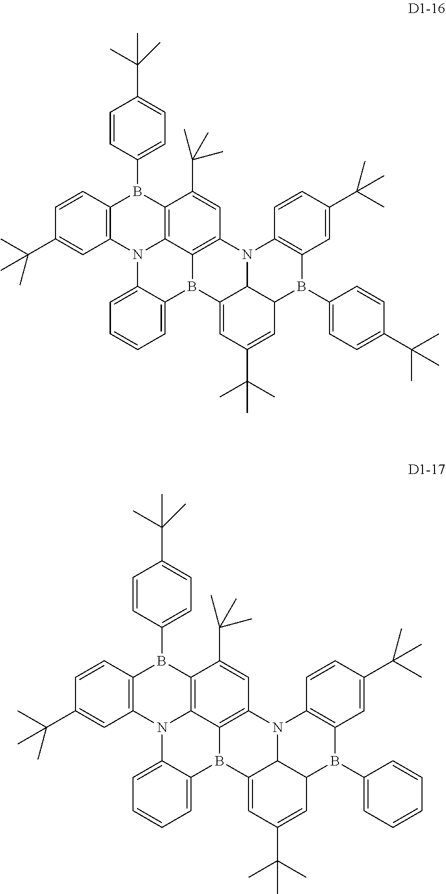

For example, in a case where X is nitrogen, Y is boron, Z is boron, X₁ is nitrogen, Y₁ is substituted carbon, A, E, and J are all six-membered carbocycles, Rb is hydrogen, R₁, Ra, and Rc are all C4 alkyl, and Rx is substituted C6 aryl, the structural formula of the first light-emitting material D1 may be as follows.

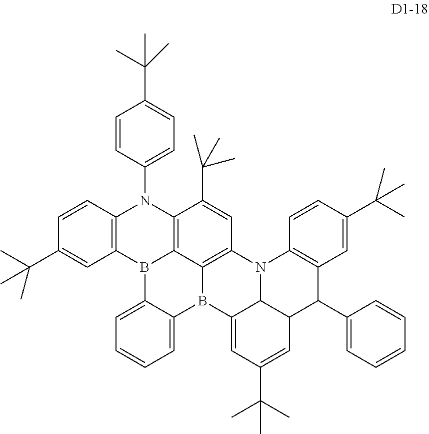 [SMILES: CC(C)(C)C1=CC2C(c3ccccc3)c3cc(C(C)(C)C)ccc3N3c4cc(C(C)(C)C)c5c6c4B(C(=C1)C23)c1ccccc1B6c1cc(C(C)(C)C)ccc1N5c1ccc(C(C)(C)C)cc1]

For example, in a case where X is nitrogen, Y is boron, Z is boron, X₁ is nitrogen, Y₁ is substituted carbon, A, E, and J are all six-membered carbocycles, Rb is hydrogen, R₁, Ra, and Rc are all C4 alkyl, Rx is substituted C6 aryl, and Rx is bonded to A by a covalent bond, the structural formula of the first light-emitting material D1 may be as follows.

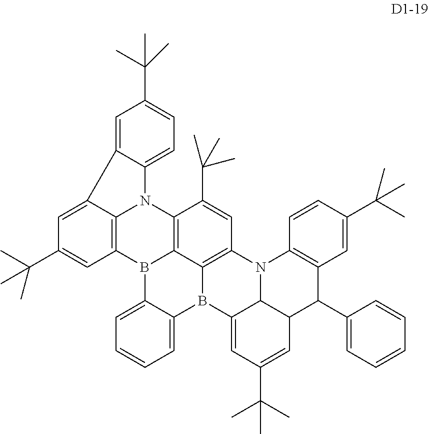 [SMILES: CC(C)(C)C1=CC2C(c3ccccc3)c3cc(C(C)(C)C)ccc3N3c4cc(C(C)(C)C)c5c6c4B(C(=C1)C23)c1ccccc1B6c1cc(C(C)(C)C)cc2c3cc(C(C)(C)C)ccc3n-5c12]

For example, in a case where X is nitrogen, Y is boron, Z is boron, X₁ is nitrogen, Y₁ is substituted silicon, A, E, and J are all six-membered carbocycles, Rb is hydrogen, R₁, Ra, and Rc are all C4 alkyl, and Rx is substituted C6 aryl, the structural formula of the first light-emitting material D1 may be as follows.

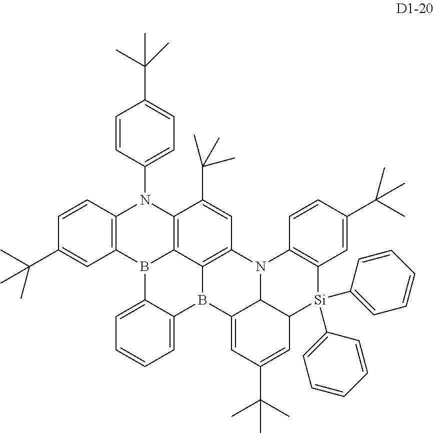 [SMILES: CC(C)(C)C1=CC2C3C(=C1)B1c4ccccc4B4c5cc(C(C)(C)C)ccc5N(c5ccc(C(C)(C)C)cc5)c5c(C(C)(C)C)cc(c1c54)N3c1ccc(C(C)(C)C)cc1[Si]2(c1ccccc1)c1ccccc1]

It will be noted that the structural formulas listed above are examples of the structure of the first light-emitting material D1 and are not limitations on the structure of the first light-emitting material D1. “D1-x” for the above structural formula is the name of each structural formula and is not part of the structure of the structural formula, where x is a positive integer, and the same applies the following.

In some embodiments, the molecular weight of the first light-emitting material D1 is less than or equal to 1250.

For example, the molecular weight of the first light-emitting material D1 is less than 1250; alternatively, the molecular weight of the first light-emitting material D1 is equal to 1250. For example, the molecular weight of the first light-emitting material D1 may be 300, 400, 550, 800, 1000, 1250, or the like, which is not limited here.

It will be understood that in a case where the molecular weight of the first light-emitting material D1 is greater than 1250, the first light-emitting material D1 has relatively poor compatibility with the manufacturing process of the light-emitting device 100 in the related art. The manufacturing process of the light-emitting device 100 is, for example, evaporation. In the embodiments of the present disclosure, the molecular weight of the first light-emitting material D1 is set to be less than or equal to 1250, the first light-emitting material D1 may be compatible with the manufacturing process of the light-emitting device 100 in the related arts, such as evaporation, thereby reducing the manufacturing cost of the light-emitting device 100.

In some embodiments, at least one light-emitting layer 131 further includes a second light-emitting material D2; the singlet energy level S1(D2) of the second light-emitting material D2 is less than the singlet energy level S1(D1) of the first light-emitting material D1, and the triplet energy level T1(D2) of the second luminescent material D2 is greater than the triplet energy level T1(D1) of the first light-emitting material D1, that is, S1(D2)<S1(D1), and T1(D2)>T1(D1).

It will be understood that, in a case of S1(D2)<S1(D1), the second light-emitting material D2 may quench excess excitons in the light-emitting layer 131 and improve the device life of the light-emitting device 100; furthermore, at the singlet energy level, the addition of the second light-emitting material D2 will not affect the reception of energy, transmitted from the first host material H1 and/or the second host material H2, by the first light-emitting material D1. Thus, the first light-emitting material D1 may receive the energy transmitted by the first host material H1 and/or the second host material H2 to achieve the light-emitting function. In a case of T1(D2)>T1(D1), at the triplet energy level, the second light-emitting material D2 may transmit energy to the first light-emitting material D1, which realizes the effective energy transmission from the second light-emitting material D2 to the first light-emitting material D1 at the triplet energy level. In this way, at the triplet energy level, the first host material H1 and/or the second host material H2 may first transfer energy to the second light-emitting material D2, and then the second light-emitting material D2 transfers energy to the first light-emitting material D1, which may ameliorate the problem of being prone to quenching caused by the slow energy transfer process of the first host material H1 and/or the second host material H2 at the triplet energy level, so that the overall luminous efficiency of the light-emitting device 100 is improved.

For example, the singlet energy level S1(D2) of the second light-emitting material D2 is less than the singlet energy level S1(D1) of the first light-emitting material D1, and the singlet energy level S1(D1) of the first light-emitting material D1 is less than the singlet energy level S1(H2) of the second host material H2; the triplet energy level T1(H2) of the second host material H2 is greater than the triplet energy level T1(D2) of the second light-emitting material D2, and the triplet energy level T1(D2) of the second light-emitting material D2 is greater than the triplet energy level T1(D1) of the first light-emitting material D1. That is, S1(D2)<S1(D1)<S1(H2), and T1(H2)>T1(D2)>T1(D1).

It will be understood that, in a case of S1(D2)<S1(D1)<S1(H2), at the singlet energy level, the order of energy transfer is the second host material H2, the first light-emitting material D1, and the second light-emitting material D2, which realizes the effective energy transmission from the second host material H2 to the first light-emitting material D1 at the singlet energy level. Thus, the addition of the second light-emitting material D2 does not affect the reception of energy transmitted from the second host material H2 by the first light-emitting material D1, so that the luminous efficiency of the light-emitting device 100 is improved. In a case of T1(H2)>T1(D2)>T1(D1), at the triplet energy level, the order of energy transfer is the second host material H2, the second light-emitting material D2, and the first light-emitting material D1. Thus, at the triplet energy level, the second host material H2 may first transfer energy to the second light-emitting material D2, and then the second light-emitting material D2 transfers energy to the first light-emitting material D1, which may ameliorate the problem of being prone to quenching caused by the slow energy transfer process of the second host material H2 at the triplet energy level, so that the overall luminous efficiency of the light-emitting device 100 is improved.

In some embodiments, the second light-emitting material D2 is a phosphorescent material, or a delayed fluorescent material. In some other embodiments, the second light-emitting material D2 may be selected from the structures shown in the above general formula I, as long as the requirements that the singlet energy level S1(D2) of the second light-emitting material D2 is less than the singlet energy level S1(D1) of the first light-emitting material D1, and the triplet energy level T1(D2) of the second light-emitting material D2 is greater than the triplet energy level T1(D1) of the first light-emitting material D1 are satisfied, which is not limited here.

In some embodiments, the mass proportion of the second light-emitting material D2 in the light-emitting layer 131 is less than or equal to 5% and greater than or equal to 0.1%. For example, the mass proportion of the second light-emitting material D2 in the light-emitting layer 131 is 0.1%, 0.5%, 1.0%, 2.0%, 3.0%, 4.0%, 5.0%, or the like, which is not limited here. In a case where the mass proportion of the second light-emitting material D2 in the light-emitting layer 131 is less than 0.1%, it is possible to affect the function of the second light-emitting material D2 in improving the overall luminous efficiency of the light-emitting device 100. In a case where the mass proportion of the second light-emitting material D2 in the light-emitting layer 131 is greater than 5%, the second light-emitting material D2 emits relatively more light, which cannot meet the light-emitting requirements of the light-emitting device 100; furthermore, it is possible to increase the amount of light emitted by the second light-emitting material D2, while the light emitting process at the triplet energy level is relatively slow and prone to quenching, which affects the overall luminous efficiency of the light-emitting device 100.

In order to objectively evaluate technical effects of the embodiments of the present disclosure, detailed exemplary description of the solutions provided by the embodiments in the present application is made through the following Embodiments and Comparative example.

In the following Embodiments and Comparative examples, different materials are used to form the light-emitting layer 131 of the light-emitting device 100, and the voltage, luminous efficiency, device life, color of emitted light, and efficiency attenuation ΔE of the light-emitting unit 130 of the light-emitting device 100 are compared. The color of the emitted light is represented by the chromaticity coordinates CIEx and CIEy in the CIE chromaticity diagram.

In the related arts, the CIE chromaticity diagram is a color system created by the International Commission on Illumination (CIE). In the color system, color attributes may be represented by the chromaticity coordinates CIEx and CIEy.

In the following Comparative examples and Embodiments, the structures of the light-emitting devices 100 and the test conditions of the light-emitting devices 100 are the same.

For example, referring to FIG. 4, the method of manufacturing the light-emitting device 100 is as follows: forming the first electrode 110, the hole injection layer 140, the hole transport layer 150, the electron blocking layer 160, the light-emitting layer 131, the hole blocking layer 190, the electron transport layer 180, the electron injection layer 170 and the second electrode 120 on the backplate in sequence by respectively using the material (indium tin oxide) of the first electrode 110, the material of the hole injection layer 140, the material of the hole transport layer 150, the material of the electron blocking layer 160, the material of the light-emitting layer 131, the material of the hole blocking layer 190, the material of the electron transport layer 180, the material of the electron injection layer 170 and the material of the second electrode 120. The processes of forming the first electrode 110, the hole injection layer 140, the hole transport layer 150, the electron blocking layer 160, the light-emitting layer 131, the hole blocking layer 190, the electron transport layer 180, the electron injection layer 170 and the second electrode 120 are each, for example, evaporation.

It will be noted that the light-emitting devices 100 in Comparative example and Embodiment are each the light-emitting device 100 in which the light-emitting layer 131 is a single-layer, i.e., the light-emitting device 100 in which each light-emitting unit 130 includes one light-emitting layer 131. For the first electrodes 110, the hole injection layers 140, the hole transport layers 150, the electron blocking layers 160, the hole blocking layers 190, the electron transport layers 180, the electron injection layers 170, and the second electrodes 120 in the Embodiments and Comparative examples, the thicknesses and materials are respectively the same; for the light-emitting layers 131, the thicknesses are the same and both are 30 nm, and the materials are not exactly the same.

The light-emitting layer 131 in the following Comparative examples includes a contrast light-emitting material. The contrast light-emitting material involved in the following Comparative examples include:

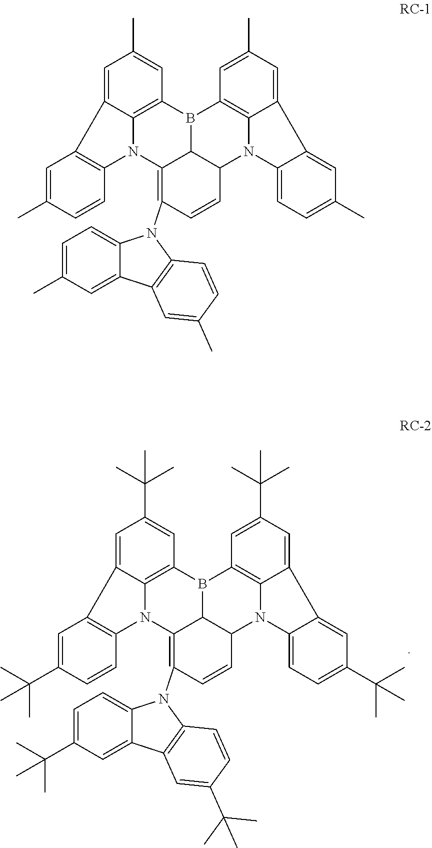

It will be noted that, each of “RC-1” and “RC-2” for the above structural formulas is the name of the respective structural formula and is not part of the structure of the structural formula.

The materials of the light-emitting layers 131 in Embodiments and Comparative examples are described below respectively.

In Embodiment 1, the light-emitting layer 131 includes a first host material H1, a second host material H2 and a first light-emitting material D1; the structural formula of the first host material H1 is as shown in H1-6, and the mass proportion of the first host material H1 in the light-emitting layer 131 is 69%; the structural formula of the second host material H2 is as shown in H2-17, and the mass proportion of the second host material H2 in the light-emitting layer 131 is 30%; the structural formula of the first light-emitting material D1 is as shown in D1-13, and the mass proportion of the first light-emitting material D1 in the light-emitting layer 131 is 1%.

In Embodiment 2, the light-emitting layer 131 includes a first host material H1, a second host material H2 and a first light-emitting material D1; the structural formula of the first host material H1 is as shown in H1-6, and the mass proportion of the first host material H1 in the light-emitting layer 131 is 69%; the structural formula of the second host material H2 is as shown in H2-17, and the mass proportion of the second host material H2 in the light-emitting layer 131 is 30%; the structural formula of the first light-emitting material D1 is as shown in D1-16, the mass proportion of the first light-emitting material D1 in the light-emitting layer 131 is 1%.

In Embodiment 3, the light-emitting layer 131 includes a first host material H1, a second host material H2 and a first light-emitting material D1; the structural formula of the first host material H1 is as shown in H1-6, and the mass proportion of the first host material H1 in the light-emitting layer 131 is 79%; the structural formula of the second host material H2 is as shown in H2-17, and the mass proportion of the second host material H2 in the light-emitting layer 131 is 20%; the structural formula of the first light-emitting material D1 is as shown in D1-13, and the mass proportion of the first light-emitting material D1 in the light-emitting layer 131 is 1%.

In Embodiment 4, the light-emitting layer 131 includes a first host material H1, a second host material H2 and a first light-emitting material D1; the structural formula of the first host material H1 is as shown in H1-6, and the mass proportion of the first host material H1 in the light-emitting layer 131 is 59%; the structural formula of the second host material H2 is as shown in H2-17, and the mass proportion of the second host material H2 in the light-emitting layer 131 is 40%; the structural formula of the first light-emitting material D1 is as shown in D1-13, and the mass proportion of the first light-emitting material D1 in the light-emitting layer 131 is 1%.

In Embodiment 5, the light-emitting layer 131 includes a first host material H1, a second host material H2 and a first light-emitting material D1; the structural formula of the first host material H1 is as shown in H1-6, and the mass proportion of the first host material H1 in the light-emitting layer 131 is 69.5%; the structural formula of the second host material H2 is as shown in H2-17, and the mass proportion of the second host material H2 in the light-emitting layer 131 is 30%; the structural formula of the first light-emitting material D1 is as shown in D1-16, and the mass proportion of the first light-emitting material D1 in the light-emitting layer 131 is 0.5%.

In Embodiment 6, the light-emitting layer 131 includes a first host material H1, a second host material H2 and a first light-emitting material D1; the structural formula of the first host material H1 is as shown in H1-6, and the mass proportion of the first host material H1 in the light-emitting layer 131 is 68.5%; the structural formula of the second host material H2 is as shown in H2-17, and the mass proportion of the second host material H2 in the light-emitting layer 131 is 30%; the structural formula of the first light-emitting material D1 is as shown in D1-16, and the mass proportion of the first light-emitting material D1 in the light-emitting layer 131 is 1.5%.

In Comparative example 1, the light-emitting layer 131 includes a first host material H1 and a second host material H2; the structural formula of the first host material H1 is as shown in H1-6, and the mass proportion of the first host material H1 in the light-emitting layer 131 is 70%; the structural formula of the second host material H2 is as shown in H2-17, and the mass proportion of the second host material H2 in the light-emitting layer 131 is 30%. The light-emitting layer 131 does not include the first light-emitting material D1.

In Comparative example 2, the light-emitting layer 131 includes a first host material H1 and a first light-emitting material D1; the structural formula of the first host material H1 is shown in H1-6, and the mass proportion of the first host material H1 in the light-emitting layer 131 is 99%; the structural formula of the first light-emitting material D1 is as shown in D1-13, and the mass proportion of the first light-emitting material D1 in the light-emitting layer 131 is 1%. The light-emitting layer 131 does not include the second light-emitting material D2.

In Comparative example 3, the light-emitting layer 131 includes a first host material H1, a second host material H2 and a contrast light-emitting material; the structural formula of the first host material H1 is as shown in H1-6, and the mass proportion of the first host material H1 in the light-emitting layer 131 is 69%; the structural formula of the second host material H2 is as shown in H2-17, and the mass proportion of the second host material H2 in the light-emitting layer 131 is 30%; the structural formula of the contrast light-emitting material is as shown in RC-1, and the mass proportion of the contrast light-emitting material in the light-emitting layer 131 is 1%.

In Comparative example 4, the light-emitting layer 131 includes a first host material H1, a second host material H2 and a contrast light-emitting material; the structural formula of the first host material H1 is as shown in H1-6, and the mass proportion of the first host material H1 in the light-emitting layer 131 is 69%; the structural formula of the second host material H2 is as shown in H2-17, and the mass proportion of the second host material H2 in the light-emitting layer 131 is 30%; the structural formula of the contrast light-emitting material is as shown in RC-2, and the mass proportion of the contrast light-emitting material in the light-emitting layer 131 is 1%.

In order to more clearly describe the differences in the structural formulas as well as the mass proportions in the light-emitting layer 131 of the first host material H1, the second host material H2 and the first light-emitting material D1 used in Embodiments and Comparative examples, Table 1 below is used to clearly show the differences in the structural formulas as well as the mass proportions in the light-emitting layer 131 of the first host material H1, the second host material H2 and the first light-emitting material D1 used in Embodiments and Comparative examples.

TABLE 1

| | | Second host material | First light-emitting | Contrast light-emitting |
|---|---|---|---|---|
| | First host material H1 | H2 and mass | material D1 and mass | material and mass |
| | and mass proportion | proportion thereof in | proportion thereof in | proportion thereof in |
| | thereof in the | the light-emitting | the light-emitting | the light-emitting |
| | light-emitting layer | layer | layer | layer |
| Embodiment 1 | H1-6; 69% | H2-17; 30% | D1-13; 1% | / |
| Embodiment 2 | H1-6; 69% | H2-17; 30% | D1-16; 1% | / |
| Embodiment 3 | H1-6; 79% | H2-17; 20% | D1-13; 1% | / |
| Embodiment 4 | H1-6; 59% | H2-17; 40% | D1-13; 1% | / |
| Embodiment 5 | H1-6; 69.5% | H2-17; 30% | D1-16; 0.5% | / |
| Embodiment 6 | H1-6; 68.5% | H2-17; 30% | D1-16; 1.5% | / |
| Comparative | H1-6; 70% | H2-17; 30% | / | / |
| example 1 | | | | |
| Comparative | H1-6; 99% | / | D1-13; 1% | / |
| example 2 | | | | |
| Comparative | H1-6; 69% | H2-17; 30% | / | RC-1; 1% |
| example 3 | | | | |
| Comparative | H1-6; 69% | H2-17; 30% | / | RC-2; 1% |
| example 4 | | | | |

It will be noted that “/” in Table 1 means that the light-emitting layer 131 does not include the material corresponding to the sub-grid. For example, the sub-grid corresponding to the second host material H2 and the mass proportion thereof in Comparative example 2 is “/”, which means that the light-emitting layer 131 of Comparative example 2 does not include the second host material H2. “A-x; y %” in Table 1 means that the corresponding structural formula is A-x and the corresponding mass proportion is y %. For example, the content of the sub-grid corresponding to the first host material H1 and the mass proportion thereof in the light-emitting layer 131 in Embodiment 1 is “H1-6; 69%”, which means that in the light-emitting layer 131 in Embodiment 1, the structural formula of the first host material H1 is shown as H1-6, and the mass proportion of the first host material H1 in the light-emitting layer 131 is 69%. As for the structural formulas represented by H1-x, H2-x, D1-x, and RC-x (x is a positive integer), reference may be made to the above description, which will not be repeated here.

The highest occupied molecular orbital (HOMO) level, the lowest unoccupied molecular orbital (LOMO) level, the singlet energy level (S1), the triplet energy level (T1), the hole mobility, and the electron mobility of the first host material H1, the second host material H2, the first light-emitting material D1, and the contrast light-emitting material that are shown in Table 1 are shown in Table 2.

TABLE 2

| | | | | | Hole | Electron |
|---|---|---|---|---|---|---|
| Com- | HOMO | LUMO | S1 | T1 | mobility | mobility |
| pound | (eV) | (eV) | (eV) | (eV) | (cm²/V · s) | (cm²/V · s) |
| H1-6 | −5.92 | −2.52 | 3.33 | 2.86 | 1.94*10⁻⁷ | — |
| H2-17 | −6.05 | −3.46 | 2.65 | 2.60 | — | 1.21*10⁻⁶ |
| D1-13 | −5.71 | −3.41 | 2.30 | 2.25 | — | — |
| D1-16 | −5.79 | −3.42 | 2.35 | 2.20 | — | — |
| RC-1 | −5.41 | −3.05 | 2.34 | 2.27 | — | — |
| RC-2 | −5.48 | −3.14 | 2.36 | 2.28 | — | — |

It will be noted that the units of the highest occupied molecular orbital (HOMO) level, lowest unoccupied molecular orbital energy (LOMO) level, singlet energy level (S1), and triplet energy level (T1) in Table 2 are each electron volt, and the symbols is eV; the units of the hole mobility and electron mobility are each square centimeter/(volt·second), and the symbol is cm²/V·s. “-” in Table 2 means that the parameter corresponding to the sub-grid is not listed in the present disclosure. For example, the sub-grid corresponding to the electron mobility of the first host material H1 is “-”, which means that the electron mobility of the first host material H1 in the present disclosure does not listed. As for the structural formulas represented by H1-x, H2-x, D1-x, and RC-x (x is a positive integer), reference may be made to the above description, which will not be repeated here.

Based on the above materials, the performance of voltage (V), luminous efficiency (cd/A), device life, color of emitted light and efficiency attenuation ΔE of the light-emitting devices 100 in Embodiments 1 to 6 and Comparative Examples 1 to 4 are tested. The data results of the voltage (V), luminous efficiency (e.g., represented by the current efficiency, cd/A), and device life in Embodiment 1 are based on the data results in Embodiment 1, and the test results are shown in Table 3 below. The device life is represented by the parameter LT95, and the color of the emitted light is represented by the chromaticity coordinates CIEx and CIEy in the CIE chromaticity diagram.

TABLE 3

| | | Luminous | | | | |
|---|---|---|---|---|---|---|
| | Voltage | efficiency | CIEx | CIEy | LT95 | ΔE |
| Embodiment 1 | 100% | 100% | 0.330 | 0.645 | 100% | 5.3% |
| Embodiment 2 | 100.0% | 99.6% | 0.295 | 0.668 | 99.7% | 6.2% |
| Embodiment 3 | 100.6% | 102.8% | 0.325 | 0.647 | 85.2% | 6.9% |
| Embodiment 4 | 100.8% | 88.1% | 0.336 | 0.641 | 116.1% | 4.0% |
| Embodiment 5 | 100.3% | 94.6% | 0.300 | 0.658 | 110.3% | 4.4% |
| Embodiment 6 | 100.3% | 102.8% | 0.295 | 0.671 | 101.9% | 7.0% |
| Comparative | 101.7% | 65.8% | 0.325 | 0.647 | 91.7% | 8.3% |
| example 1 | | | | | | |
| Comparative | 102.7% | 23.2% | 0.330 | 0.645 | 11.1% | 15.1% |
| example 2 | | | | | | |
| Comparative | 105.8% | 61.0% | 0.248 | 0.680 | 65.0% | 12.2% |
| example 3 | | | | | | |
| Comparative | 104.5% | 75.9% | 0.269 | 0.666 | 87.2% | 13.5% |
| example 4 | | | | | | |

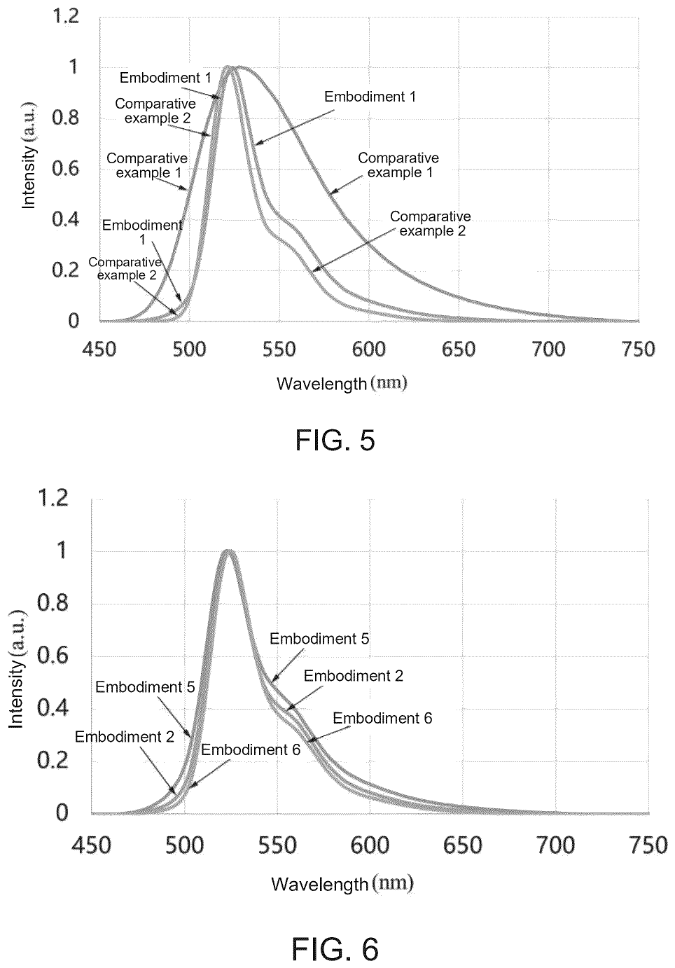

Based on the above materials, the emission spectra of the light-emitting devices 100 corresponding to Embodiment 1, Embodiment 2, Embodiment 5, Embodiment 6, Comparative example 1 and Comparative example 2 are tested. The emission spectra of the light-emitting devices 100 corresponding to Embodiment 1, Comparative example 1 and Comparative example 2 is shown in FIG. 5, and the emission spectrum of the light-emitting devices 100 corresponding to Embodiment 2, Embodiment 5 and Embodiment 6 is shown in FIG. 6.

It will be noted that in FIGS. 5 and 6, light is emitted at a wavelength of 550 nm in all the emission spectra corresponding to Embodiment 1, Embodiment 2, Embodiment 5, Embodiment 6, Comparative example 1 and Comparative example 2, and the light-emitting intensity at the wavelength of 550 nm in the emission spectrum corresponding to Comparative example 2 is weakest, which indicates that in a case where the light-emitting layer 131 includes the second host material H2, the light-emitting intensity at wavelength of 550 nm in the emission spectra is improved. Therefore, the intensity of the light emitted at the wavelength of 550 nm may characterize the intrinsic emission of the second host material H2, i.e., the radiant transition process of the second host material H2 itself. In other words, the intensity of the light emitted at the wavelength of 550 nm may characterize the relative magnitude of the light intensity emitted by the second host material itself. Moreover, the higher the intensity of the light emitted at the wavelength of 550 nm, the stronger the intrinsic emission of the second host material H2.

By comparing Embodiment 1 with Comparative examples 1 and 2, referring to Table 3, the luminous efficiency of Embodiment 1 is significantly improved, and the order of luminous efficiency from high to low is: Embodiment 1, Comparative example 1, Comparative example 2, which is due to a fact that both the second host material H2 and the first light-emitting material D1 have a radiant transition process in which electrons and holes recombine in themselves to form excitons, and the luminous efficiency of the second host material H2 itself is much higher than that of the first light-emitting material D1; it indicates that the second host material H2 has a good internal quantum efficiency and exciton yield.

By comparing Embodiment 1 with Comparative example 1, referring to FIG. 5, the emission spectrum of Embodiment 1 is significantly narrower and closer to the emission spectrum of Comparative example 2, which indicates that in Embodiment 1, the second host material H2 transfers the Forster energy to the first light-emitting material D1 to enable the first light-emitting material D1 to emit light.

By comparing Embodiment 1 with Comparative example 2, referring to FIG. 5, the intensity of the light emitted at the wavelength of 550 nm in Embodiment 1 is significantly higher, which is due to the fact that during the light emitting process of Embodiment 1, a radiative transition process, in which electrons and holes recombine in itself to form excitons, of the first light-emitting material D1 exists, and while the second host material H2 transfers the energy to the first light-emitting material D1, a radiative transition process of the second host material H2 itself also exists.

By comparing Embodiment 1 with Embodiments 3 and 4, referring to Table 3, the order of luminous efficiency from high to low is: Embodiment 3, Embodiment 1, Embodiment 4; the order of device life from long life to short life is: Embodiment 4, Embodiment 1, and Embodiment 3; and the order of efficiency attenuation ΔE from small to great is: Embodiment 4, Embodiment 1, Embodiment 3. As the doping ratio of the second host material H2 increases, the excited state density of the second host material H2 decreases. The decrease in excited state density of the second host material H2 leads to a decrease in luminous efficiency. However, due to the decrease in excited state density of the second host material H2, it is possible to prevent the energy quenching of the second host material H2 to some extent, so that the device life is improved, the difference in the number of excitons at different gray scales is reduced, and the efficiency attenuation ΔE is reduced.

By comparing Embodiment 2 with Embodiments 5 and 6, referring to Table 3, the order of luminous efficiency from high to low is: Embodiment 6, Embodiment 2, Embodiment 5; the order of efficiency attenuation ΔE from small to great is: Embodiment 5, Embodiment 2, Embodiment 6; the order of device life is: Embodiment 5, Embodiment 6, Embodiment 2; referring to FIG. 6, as the doping ratio of the first light-emitting material D1 increases, the intensity of the light emitted at the wavelength of 550 nm decreases. As the doping ratio of the first light-emitting material D1 increases, the energy transfer from the second host material H2 to the first light-emitting material D1 becomes more complete, that is, the first light-emitting material D1 mainly emits light, and the second host material H2 emits less or no light, so that the intensity of the light emitted at 550 nm is reduced. Moreover, as the doping ratio of the first light-emitting material D1 increases, the energy transfer channels from the second host material H2 to the first light-emitting material D1 increases, resulting in an increase in the energy transfer from the second host material H2 to the first light-emitting material D1, which manifests as an increase in luminous efficiency. However, the energy transfer from the second host material H2 to the first light-emitting material D1 is increased, resulting in an increase in the excited state density of the first light-emitting material D1, which increases the energy quenching of the first light-emitting material D1 to a certain extent, so that the device life is reduced, the difference in the number of excitons at different gray scales is increased and the efficiency attenuation ΔE is increased.

By comparing Embodiment 1 with Comparative examples 3 and 4, referring to Table 3, the luminous efficiency of Comparative Examples 3 and 4 is significantly reduced, which is due to a great difference in highest occupied molecular orbital (HOMO) level of both the contrast light-emitting materials RC-1 and RC-2 in Comparative examples 3 and 4 and the first host material H1 and the second host material H2; the difference is greater than 0.3 eV, it is easy to generate hole traps, causing the contrast light-emitting materials RC-1 and RC-2 to easily acquire holes, so that the exciton yield is reduced, and the luminous efficiency is reduced.

The light-emitting devices 100 in Embodiments 1 to 6 are selected from the light-emitting devices 100 in some of the embodiments of the present disclosure. From the above analysis, by comparing Embodiments 1 to 6 with Comparative examples 1 to 4, it can be seen that the light-emitting devices 100 in Embodiments 1 to 6 all have device performance of low voltage, high efficiency, and long life, and the efficiency attenuation ΔE is small, which may be less than or equal to 7%, so that it is conducive to high-quality image display effects.

It can be seen that in the present disclosure, the light-emitting layer 131 includes the first host material H1, the second host material H2 and the first light-emitting material D1, and the proportion of the number of photons emitted by the first light-emitting material D1 and the proportion of the number of photons emitted by the second channel are limited, so that the light-emitting device 100 has device performance of low voltage, high efficiency, and long life, and the efficiency attenuation ΔE value is small. Thus, it is possible to ameliorate the problem of color cast at different gray scales, and reduce the display differences at different gray scales; moreover, in a case where the efficiency attenuation ΔE is small, the difference in efficiency attenuation trends of the currents of red (R), green (G), and blue (B) colors at different gray scales may be reduced, the problem of greenish and reddish at a low gray scale is ameliorated, and the problem of the excessive difference in luminous efficiency between low luminance and high luminance is ameliorated, which is conducive to high-quality image display effects and achieves normal display effects at different gray scales.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. A light-emitting device, comprising:
a first electrode and a second electrode that are arranged in sequence; and
at least one light-emitting unit disposed between the first electrode and the second electrode;
wherein the at least one light-emitting unit includes a light-emitting layer, and the light-emitting layer includes: a first host material, a second host material, and a first light-emitting material;
photons emitted by the first light-emitting material include: photons emitted due to energy obtained by fluorescence resonance energy transfer of the first host material and/or the second host material, and photons emitted due to excitons formed by recombination of electrons and holes; and
a ratio of a number of the photons emitted by the first light-emitting material to a number of photons emitted by the light-emitting layer is greater than 80%; a ratio of a number of the photons emitted by the first light-emitting material due to the energy obtained by fluorescence resonance energy transfer of the first host material and/or the second host material to the number of the photons emitted by the first light-emitting material is greater than 60%.

2. The light-emitting device according to claim 1, wherein a mass proportion of the first light-emitting material in the light-emitting layer is less than or equal to 5% and greater than or equal to 0.5%.

3. The light-emitting device according to claim 1, wherein an absolute value of a difference between a highest occupied molecular orbital level of the first light-emitting material and greater one of a highest occupied molecular orbital level of the first host material and a highest occupied molecular orbital level of the second host material is less than or equal to 0.25 eV.

4. The light-emitting device according to claim 1, wherein
a singlet energy level of the first host material is greater than a singlet energy level of the first light-emitting material;
a singlet energy level of the second host material is greater than the singlet energy level of the first light-emitting material;
a triplet energy level of the first host material is greater than a triplet energy level of the first light-emitting material; and
a triplet energy level of the second host material is greater than the triplet energy level of the first light-emitting material.

5. The light-emitting device according to claim 1, wherein a lowest unoccupied molecular orbital level of the first light-emitting material is greater than smaller one of a lowest unoccupied molecular orbital level of the first host material and a lowest unoccupied molecular orbital level of the second host material.

6. The light-emitting device according to claim 1, wherein a hole mobility of the first host material is greater than an electron mobility of the first host material; an electron mobility of the second host material is greater than a hole mobility of the second host material; a ratio of the hole mobility of the first host material to the electron mobility of the second host material is greater than or equal to 0.1.

7. The light-emitting device according to claim 1, wherein an electron mobility of the first host material is greater than a hole mobility of the first host material; a hole mobility of the second host material is greater than an electron mobility of the second host material; a ratio of the hole mobility of the second host material to the electron mobility of the first host material is greater than or equal to 0.1.

8. The light-emitting device according to claim 1, wherein at least one of an internal quantum efficiency of the first host material and an internal quantum efficiency of the second host material is greater than or equal to 30%.

9. The light-emitting device according to claim 1, wherein a ratio of a mass proportion of the first host material in the light-emitting layer to a mass proportion of the second host material in the light-emitting layer is greater than or equal to 0.25 and less than or equal to 4.

10. The light-emitting device according to claim 1, wherein an absolute value of a difference between a highest occupied molecular orbital level of the first host material and a highest occupied molecular orbital level of the second host material is less than or equal to 0.25 eV.

11. The light-emitting device according to claim 1, wherein the first light-emitting material is selected from any of structures represented by the following general formula I: 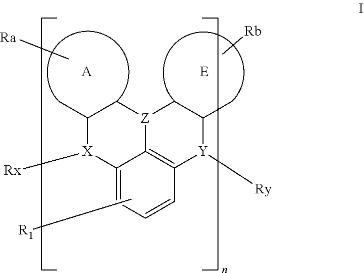
X, Y and Z are the same or different, and are independently selected from any of C(Re), N, B, P, P═O, Si(Re), S and a single bond; a value of n is selected from any of 1, 2, 3 and 4;
A and E are the same or different, and are independently selected from any of five-membered or six-membered carbocycles, five-membered or six-membered carboheterocycles, and a fused ring; and
Ra, Rb, Rx, Ry, R₁ and Re are the same or different, and are independently selected from any of hydrogen, deuterium, cyano, substituted or unsubstituted C5-C50 aryl, and substituted or unsubstituted C1-C50 alkyl.

12. The light-emitting device according to claim 1, wherein the first light-emitting material is selected from any of structures represented by the following general formula II: 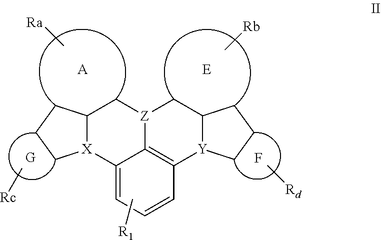
X, Y and Z are independently selected from any of C(Re), N, B, P, P═O, Si(Re), S and a single bond; and Z is different from X and Y;
A, E, F and G are the same or different, and are independently selected from any of five-membered or six-membered carbocycles, five-membered or six-membered carboheterocycles and a fused ring, and A, E, F and G are not all six-membered carbocycles; in a case where G is a six-membered carbocycle, F is not a six-membered carbocycle or does not exist; and
Ra, Rb, Rc, Rd, R₁ and Re are the same or different, and are independently selected from any of hydrogen, deuterium, cyano, substituted or unsubstituted C5-C50 aryl, and substituted or unsubstituted C1-C50 alkyl.

13. The light-emitting device according to claim 1, wherein the first light-emitting material is selected from any of structures represented by the following general formula III: 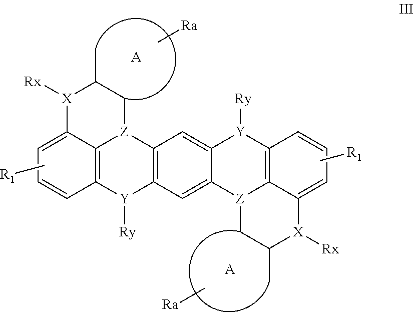
X, Y and Z are independently selected from any of C(Re), N, B, P, P═O, Si(Re), S and a single bond; X and Y are the same or different, and Z is different from X and Y;
A is selected from five-membered or six-membered carbocycle, or five-membered or six-membered carboheterocycle; and
Ra, Rx, Ry, R₁ and Re are the same or different, and are independently selected from any of hydrogen, deuterium, cyano, substituted or unsubstituted C5-C50 aryl, and substituted or unsubstituted C1-C50 alkyl.

14. The light-emitting device according to claim 1, wherein the first light-emitting material is selected from any of structures represented by the following general formula IV: 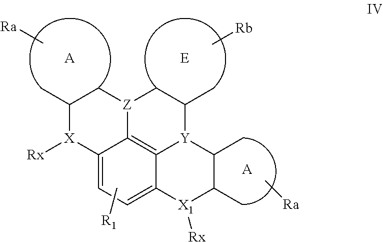
wherein X, Y, Z and X₁ are independently selected from any of C(Re), N, B, P, P═O, Si(Re), S and a single bond, and in a case where Z and Y are the same, X and X₁ are the same; in a case where Z is different from Y, X is different from X₁;
A and E are the same or different, and are independently selected from five-membered or six-membered carbocycles or carboheterocycles; A and E are not all six-membered carbocycles; and
Ra, Rb, Rx, R₁ and Re are the same or different, and are independently selected from any of hydrogen, deuterium, cyano, substituted or unsubstituted C5-C50 aryl, and substituted or unsubstituted C1-C50 alkyl.

15. The light-emitting device according to claim 1, wherein the first light-emitting material is selected from any of structures represented by the following general formula V: 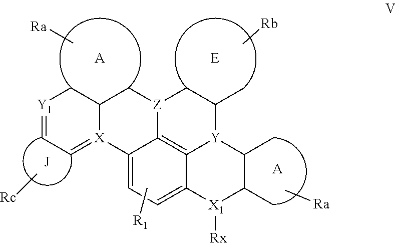
wherein X, Y, Z, X₁ and Y₁ are independently selected from any of C(Re), N, B, P, P═O, Si(Re), S and a single bond; in a case where Z is the same as Y, X is the same as X₁; in a case where Z is different from Y, X is different from X₁, and Y₁ is different from X;
A, E, and J are the same or different, and are independently selected from five-membered or six-membered carbocycles or carboheterocycles, and A, E, and J are not all six-membered carbocycles; and
Ra, Rb, Rc, Rx, R₁ and Re are the same or different, and are independently selected from any of hydrogen, deuterium, cyano, substituted or unsubstituted C5-C50 aryl, and substituted or unsubstituted C1-C50 alkyl.

16. The light-emitting device according to claim 1, wherein a molecular weight of the first light-emitting material is less than or equal to 1250.

17. The light-emitting device according to claim 1, wherein the light-emitting layer further includes a second light-emitting material; wherein
a singlet energy level of the second light-emitting material is less than a singlet energy level of the first light-emitting material; and
a triplet energy level of the second light-emitting material is greater than a triplet energy level of the first light-emitting material.

18. The light-emitting device according to claim 17, wherein a mass proportion of the second light-emitting material in the light-emitting layer is less than or equal to 5% and greater than or equal to 0.1%.

19. A display panel, comprising: the light-emitting device according to claim 1; and
a driving circuit used to drive the light-emitting device to emit light.

20. A display apparatus, comprising: the display panel according to claim 19; and
a driver chip used to drive the display panel to perform display.
